(19) United States
(12) Patent Application Publication
(10) Pub. No.: US 2011/0172110 A1
(43) Pub. Date: Jul. 14, 2011

(54) TRACERS AND ASSEMBLY FOR LABELING CHEMICAL OR BIOLOGICAL MOLECULES METHODS AND KITS USING THE SAME

(76) Inventor: Barry Merriman, Los Angles, CA (US)

(21) Appl. No.: 10/597,583

(22) PCT Filed: Jan. 19, 2005
(86) PCT No.: PCT/US05/02572

§ 371 Date: Apr. 22, 2010

Related U.S. Application Data
(60) Provisional application No. 60/540,361, filed on Jan. 30, 2004.

(51) Int. Cl. C40B 30/00; C40B 30/04; C40B 30/06; C40B 50/00; C01B 33/12; G03F 7/20; G06F 17/50; G06F 19/00; G06K 19/06; G01N 23/04

(52) U.S. Cl. 506/9; 506/7; 506/10; 506/23; 428/402; 430/323; 716/55; 702/155; 702/19; 235/494; 378/62

(57) ABSTRACT

An improved process to create an arbitrarily large number of distinguishable particles allows more flexibility in experimental design and related efficiencies of scale. Novel enhanced tracers, for example, Shape Encoded Particles (SEP's) function as indicator means, such as probe-carriers in massively multiplexed assays. Shape encoded identity provides an elegantly simple tracking mechanism, whereby binding/reaction probes coupled to SEP's surfaces can be monitored, viewed, imaged or otherwise utilized leveraging off of the generation of millions of distinct, for example, approximately 100×100×10 micron squared silicon flakes fabricated using conventional MEMS techniques. Plethoric related applications, and contemplated strategies for benefiting from the novel enhanced SEP's and their respective enabling technologies are disclosed, ranging from pearl cultering seed elements to uniquely identify resulting jewelry pieces to an improved parallel stem cell differentiation screening assays.

### CROSS-REFERENCE TO RELATED APPLICATIONS

This invention was made with support by the National Science Foundation (NSF) “Engineering Microsystems: XYZ on a chip” CMS-99-80874, and claims full Paris Convention Priority from U.S. Provisional Patent Application No. 60/540,361 filed Jan. 30, 2004.

### BACKGROUND OF THE DISCLOSURE

1. Field of the Disclosure

The present invention relates to a tracer for chemical or biological molecules or materials. In particular, the present invention relates to an elegantly simple assembly, tool, or device including a tracer and methods and kits using the same for multiplex probe deployment, identification, tracking and for related applications including but not limited to the authentication of materials either as an identifiable or embedded carrier on an optical or sub-optical scale.

2. Description of the Background Art

In various fields of technology, including but not limited to biotechnology and the chemical arts, an ongoing need exists for tracers able to provide information on molecules involved in reaction processes. A tracer is an identifiable substance or property, such as a colored dye or a radioactive isotope, that is introduced into a biological or chemical system and can be followed through the course of a process, providing information on the pattern of events in the process or on the reaction or redistribution of molecules or elements involved. Likewise, tracer mechanisms, elements and constructs that enable differentiation of other substrates from their attachments remain a longstanding need among artisans of the biochemical, molecular biological and genomic arts, among others.

An ideal tracer should be able to provide the information of interest, with minimal or no interference with the process involved. At the very least, such artifacts need to be tracked and factored in to the involved process. Frequently, this is an issue in reaction processes, where the tracer is associated with a molecule that has to efficiently react with other reagents in the process.

An example of such processes is given by chemical and biological reactions, in particular carried out to perform an assay, wherein quantitative or qualitative analysis is carded out. When such reactions are performed, a tracer that does not interfere with the molecule reactivity in the assay (and therefore does not interfere with the efficiency of the assay) is highly desirable. In particular, such a tracer is highly desirable in cases where the identity of more than one molecule involved in the assay is encoded and later decoded by means of tracers. Further, in some assays, especially in the biotechnological field, the reacting molecule identified by the tracer is often a probe and the tracer is used as a uniquely identifiable carrier, and the assays involve a wide number of such probe carriers.

Numerous systems have been devised for distinguishing large numbers of probes. A common practice is to put probes into the wells of a microtiter plate, so that distinct wells carry distinct probes. A more recent development is the so-called microarray system, in which probes are attached to a carrier surface at the nodes of a planar (X,Y) grid, so that the distinct (X,Y) locations identify the distinct probes. See, for example, the spotted cDNA microarrays developed by Dr. Patrick O. Brown, et al, Stanford University, or the DNA oligo microarrays of Affymetrix, Inc., a Santa Clara, Calif. company, www.affymetrix.com.

Various methods have been proposed and validated for means to generate two dimensional arrays of DNA probes onto flat surfaces using inkjets [4], capillary tip-based printing. Schena, M., Shalon, D, Davis, R W, and Brown, P. O. (1995). Quantitative monitoring of gene expression patterns with a complementary DNA microarray. Science, 270, 467-470, Mask or micromirror-based light deprotection [2,4], microelectronic control of pH-level (Combimatrix, www.combimatrix.com) [7], and electronic addressing of DNA probes (Nanogen, www.nanogen.com) [8].

An alternative to a physical two-dimensional array of DNA or other probes is to encode the unique identity of each probe that allows the probes to be used “en masse” and decoded distinctly at a later step. Examples of such approaches include: color-encoded plastic microsphere carriers, using distinct dye mixtures to achieve a large numbers of distinguishable microbead colors, for example, the bead system of Luminex Corporation, an Austin, Tex. company, www.luminexcorp.com, and the Quantum Dot color coding system of Quantum Dot Corporation, a Hayward, Calif. company, www.qdots.com.

Additional alternative approaches to labeling microsphere carriers include attaching distinct mixtures of DNA oligos to each microbead and capturing the microbeads into wells etched at the end of a fiberoptic bundle. Each bead can then be decoded by the bead's distinct DNA hybridization signatures after 8-16 separate hybridizations with short oligos, as developed by Illumine, Inc., a San Diego, Calif. company [11]. Special types of particles can also be encoded with radio-frequency tags. [12] or nanoscale bar codes [13] These approaches allow the multiplexing of probes in the order of tens to tens of thousands.

### SUMMARY OF THE DISCLOSURE

According to an aspect of the instant teachings a novel enhanced tracer, suitable to be used as a label of a molecule or material involved in chemical or biological reactions is disclosed. The tracer comprises a particle having a specific distinguishable shape, the shape used as a particle identifier. For example, according to an embodiment of the present disclosure, the particle has a flat, two-dimensional shape and optionally includes at least a notch as an orientation mark, and the particle is a silicon element, or aspects of the same closer in form to a flake.

According to another aspect of the present disclosure, a process for the manufacture of a tracer suitable to be used as label of a molecule involved in a chemical or biological reaction is disclosed. The process comprises shaping a suitable material into a specific distinguishable shape, for example, where the particle has a flat, two-dimensional shape, and the process comprises: outlining a desired shape in a layer of a suitable material, obtaining a shape outline in the material; and etching or impressing the shape outline into the material.

According to yet another aspect, an assembly suitable for labeling a molecule or material involved in a chemical or biological reaction is disclosed. The assembly comprises the tracer herein disclosed, and a readable support associated with the particle comprised in the tracer to make the shape of the particle and consequently the tracer distinguishable or identifiable, and for example, the readable support in the assembly is a two-dimensional support. In particular, the support can be a flat glass slide, and/or a specially patterned or adhesive surface. Such a support can also be at the base of each well of a wellplate and specifically a 96-well plate.

According to yet still another aspect, a process for manufacturing an assembly is disclosed, comprising assembling the tracer herein disclosed with a readable support suitable to be used for identifying the tracer, and that the process further comprises aiding positioning of the tracer on the support, wherein aiding positioning can be performed by mechanical agitation or vibration.

According to another and still further aspect, a method to trace a molecule or material in one or more chemical or biological reactions is disclosed, comprising coupling the material with the tracer or the assembly, for example, wherein the molecule is DNA, RNA, or a protein, and in case the molecule is DNA, the assay is preferably a DNA hybridization assay. The material could be intact cells, cell membranes, or other cellular components.

According to still yet another other and further aspect, a method to perform a reaction wherein one or more molecules (or materials) are to be labeled is disclosed. The method comprises: coupling each of the one or more molecules with a tracer or assembly, each tracer or assembly coupled with each of the one or more molecules uniquely labeling the each of the one or more molecules, wherein, for example, the method further comprises: reading the shape of the tracer coupled with each of the one or more molecules, thereby identifying the molecule.

For example, where the reaction is carried out to perform an assay, and the molecule is a biological or chemical probe to be reacted against a complex sample in the assay. Preferred molecules are DNA, RNA or a protein, and the assay is one that might otherwise be performed as a microarray-format assay, particularly a gene expression assay or polymorphism detection assay where the molecule is a DNA probe.

When the probe is an oligonucleotide, coupling of the probe with the tracer can be conveniently performed by synthesizing the oligonucleotide on the surface of the tracer, for example, where a method to perform an assay is disclosed, wherein a probe is reacted with a test sample. The method comprises coupling the tracer herein disclosed with the probe or the test sample; reacting the probe with the test sample; assembling the tracer with a readable support allowing identification of the tracer; and reading the support, thereby identifying the tracer.

The operations can be performed contemporaneously in a single step as well as at different times in multiple steps, parallel processing being preferred. Alternately, reacting the probe with the test sample is performed after coupling the tracer with the probe and before assembling the tracer with a readable support, or assembling the tracer with the readable support is performed after coupling the probe with the tracer but before reacting the probe with the test sample.

Reading of the support is performed by taking micrographic images of the support, specifically when the support is a surface, as in when a method to perform an assay wherein a probe is reacted with a test sample is disclosed. The method comprises: coupling the probe or the test sample with the assembly comprising a tracer and a readable support making the tracer identifiable; reacting the probe with the test sample; and reading the support to identify the tracer. Reacting the probe with the test sample can be performed after coupling the tracer with the probe or test sample. The probe can be a DNA probe and the assay a gene expression assay or polymorphism detection assay.

Artisans will understand that a kit of parts to label a molecule involved in a chemical or biological reaction and/or to perform an assay when a probe is reacted with a test sample is also disclosed. The kit or kits comprise a tracer comprising a particle having a specific distinguishable shape; a readable support associated with the particle to make the shape of the particle identifiable; the tracer and the readable support to be used in one of the methods herein disclosed.

Inherent in the kits herein disclosed, the tracer and support can independently be comprised in the kit in one or more compositions, wherein each tracer or support is in a composition together with a suitable vehicle carrier or auxiliary agent, or together in an assembly, wherein the assembly can be included in a composition together with a suitable carrier agent or auxiliary agent. The tracers, supports, assembly, processes, kits and methods of the disclosure can be used in applications, such as diagnosis and lab analysis, identifiable by a person skilled in the art upon reading of the disclosure.

Briefly stated, an improved process to create an arbitrarily large number of distinguishable particles allows more flexibility in experimental design and related efficiencies of scale. Novel enhanced tracers, for example, Shape Encoded Particles (SEP's) function as indicator means, such as probe-carriers in massively multiplexed assays. Shape encoded identity provides an elegantly simple tracking mechanism, whereby binding/reaction probes coupled to SEP's surfaces can be monitored, viewed, imaged or otherwise utilized leveraging off of the generation of millions of distinct, for example, approximately 100×100×10 micron squared silicon flakes fabricated using conventional MEMS techniques. Plethoric related applications, and contemplated strategies for benefitting from the novel enhanced SEP's and their respective enabling technologies are disclosed, ranging from pearl cultering seed elements to uniquely identify resulting jewelry pieces to an improved parallel stem cell differentiation screening assay.

### BRIEF DESCRIPTION OF THE DRAWINGS

The above-mentioned features and objects of the present disclosure will become more apparent with reference to the following description taken in conjunction with the accompanying drawings wherein like reference numerals denote like elements and in which:

FIG. 1 is a schematic depiction of an exemplary base design for a novel enhanced SEP, according to the teachings of the present disclosure;

FIG. 2 likewise depicts an exemplary base design for a novel enhanced SEP, according to the teachings of the present disclosure;

FIG. 3 shows a sample taken from an array of squared exemplary base designs for a novel enhanced SEP, according to the teachings of the present disclosure;

FIG. 4 illustrates a genomic labelling process for an exemplary base design for a novel enhanced SEP, according to the teachings of the present disclosure;

FIG. 5 is first step in a detailed schematic treatment of a fabrication process for an exemplary base design for a novel enhanced SEP, according to the teachings of the present disclosure;

FIG. 6 is second step in a detailed schematic treatment of a fabrication process for an exemplary base design for a novel enhanced SEP, according to the teachings of the present disclosure;

FIG. 7 is third step in a detailed schematic treatment of a fabrication process for an exemplary base design for a novel enhanced SEP, according to the teachings of the present disclosure;

FIG. 8 is a fourth step in a detailed schematic treatment of a fabrication process for an exemplary base design for a novel enhanced SEP, according to the teachings of the present disclosure;

FIG. 9 is a fifth step in a detailed schematic treatment of a fabrication process for an exemplary base design for a novel enhanced SEP, according to the teachings of the present disclosure;

FIG. 10 is a sixth step in a detailed schematic treatment of a fabrication process for an exemplary base design for a novel enhanced SEP, according to the teachings of the present disclosure;

FIG. 11 further illustrates schematically aspects of an improved process to create an arbitrarily large number of distinguishable particles, exemplified by the novel enhanced SEP's according to the teachings of the present disclosure;

FIG. 12 shows a second step in an improved process for coupling probes to the novel enhanced SEP's according to the teachings of the present disclosure;

FIG. 13 schematically illustrates a single base extension step, which follows a PCR reaction step during a process for genotyping with single base extension and the novel enhanced SEP's according to the teachings of the present disclosure;

FIG. 14 schematically illustrates hybridization to a tag array during a process for genotyping with single base extension and the novel enhanced SEP's according to the teachings of the present disclosure;

FIG. 15 demonstrates how the novel enhanced SEP's become readable at a resolution of 2 image pixels/notch according to the teachings of the present disclosure;

FIG. 16 shows an exemplary series of steps defining one way that the novel enhanced SEP's can be read in terms of shape, according to the teachings of the present disclosure; and

FIG. 17 shows an exemplary series of further steps defining one way that the novel enhanced SEP's can be read in terms of shape, according to the teachings of the present disclosure.

### DETAILED DESCRIPTION OF THE DISCLOSURE

The present inventors have discovered that novel enhanced tracers, for example, Shape Encoded Particles (SEP's) function effectively as an improved indicator means, such as a probe-carriers in massively multiplexed assays. Shape encoded identity provides an elegantly simple tracking mechanism, whereby binding/reaction probes coupled to SEP's surfaces can be monitored, viewed, imaged or otherwise utilized leveraging off of the generation of millions of distinct, for example, approximately 100×100×10 micron squared silicon flakes fabricated using conventional MEMS techniques. Plethoric related applications, and contemplated strategies for benefitting from the novel enhanced SEP's and their respective enabling technologies are possible according to the teachings of the instant disclosure, ranging from pearl cultreing seed elements to uniquely identify resulting jewelry pieces to an unexpectedly improved parallel stern cell differentiation screening assay.

Offered for consideration is a novel solution to this problem in which different probes are attached to different shapes of particles. Thus particle shape serves to encode which probe is carried by the particle. In a typical assay, the probe reports its measurement as a fluorescent signal, and both this and the carrier particle shape are recorded by an optical imaging system. Thus all probes can be deployed in a single assay reaction, and the signals and probe identities recovered after the assay is complete. The shaped particles are, for example, fabricated from silicon wafers in a cookie-cutter fashion using standard photolithography techniques. This approach is uniquely attractive because it offers unlimited coding capacity, high-quality/low-cost manufacturing, massively parallel probe attachment, deployment and reading, automated handling capabilities, and is compatible with many common types of assays. While other methods of encoding particles have been developed which offer some these advantages to varying degrees, shape encoding is especially attractive because it is extremely simple, yet offers all these advantages to a maximal degree.

In general terms, shape encoded particles are a method of identification on a microscopic scale. The major uses for such a micro-ID are as an Identifiable Carrier or an Embedded Identifier. In carrier mode, distinct “probe” materials are bound to distinct shapes, which then act as carriers that can be pooled and put through one or more “reactions”. The shapes allow the probes to be tracked through this process, and identified from the pool after all reactions are completed, In embedded mode, batches of bulk materials are mixed with quantities of distinct shapes, so that each batch contains a small concentration of shape encoded particle. The encoded batches can then be transported, dispensed, mixed, or combined with other materials, and the embedded particles allow any subsequent sample of the material to be traced back to its source, or constituent sources.

An additional practical distinction is that there are two major size regimes in which the particles can be deployed: Optical or Sub-Optical. In the optical regime (particles larger than ˜3 microns), imaging systems based on traditional light microscopy can be used to read the shapes. In the sub-optical regime (<˜3 microns), more sophisticated “imaging” techniques must be used, such as near-field, electron or atomic force microscopes.

Generally speaking, shape encoding works effectively and creates industrial efficiencies because such a method of encoding the identity of a microscopic particle by shape, works in such a way that they can be combined in large numbers and still be readily distinguished and have their individual identities recovered, it has been discovered. In the approach developed, each particle is fabricated so that it will rest on a surface (flat surface or specially patterned) in a highly restricted 3-D orientation (“lay flat”), and display a definite outline (“shape”) in this orientation, when imaged by a suitable imaging technique.

The resultant distinctive shape is used for the identification of the particle, and also any material previously associated with the particle through binding or contact. The particle dimensions can range from the millimeter to nanometer scale, and shape detection makes use of any suitable imaging system, for example: optical microscopy imaging, or non-optical imaging methods such as near-field microscopy, electron microscopy, scanning-tunneling electron microscopy, or atomic force microscopy in order to resolve smaller length scales, typically in combination with software for automated image recognition.

Likewise, the present inventors have realized that a shape encoded particle, as above, but specifically in the size range below that which can be read with optical imaging, i.e. the shapes distinctive features are smaller than the wavelength of visible light (<˜400 nanometers), and the entire particle diameter is below several microns. Such particles are to be imaged for purposes of shape decoding with or non-optical imaging methods such as near-field microscopy, electron microscopy, scanning-tunneling electron microscopy, or atomic force microscopy in order to resolve smaller length scales and thereby create a synthetic image. Such particles can be put to the same uses as super-optical scale particles, but allow greater numbers of particles to be used in such applications, as well as enabling new applications, such as those that require releasing many particles within microscopic confined spaces, such as an individual cell or even a cell nucleus, for example, as well as others specifically detailed in claims below.

A shape encoded particle, as described above, is used to carry a material bound to its surface. The distinctive shape is used for the identification of the particle and the material bound to the particle, or to track the history of exposures as the particle undergoes a series of processing/reaction steps that may alter its state or the state of the bound material. This process will typically result in some form of reporter signal from the bound material. In this case, the data acquisition process includes steps to record the reporter signal at the end of the reactions, and such a step may or may not be distinct from the imaging used to identify the particle. Further, the process also includes a means of associating the shape codes of the particles with the reporter signals, for example; processing a single image source that contains both shape information and reporter intensity, spatially registering multiple images that separately record shape and reporter signal intensity, or sorting particles into groups based on reporter signal intensity, prior to imaging for shape decoding.

Likewise, it has been discovered that shape encoded particles function as probe carriers for massively multiplexed assays. This is particularly true in that the shape encoding allows for massive simultaneous tracking of the bound probes as they are pooled and put through a single reaction, or a series of pooled reactions.

Of further interest is shape encoded particles for multiplexed, high throughput flow sorting assays. Probes are attached to shape encoded particles, reacted against a sample, and the particles are then physically sorted into two or more classes based on the strength of the reporter signals using high throughput means such as a flow cytometer cell sorter or other automated picking system. After sorting, the probes landing in different classes are decoded by imaging the shapes in each class. This provides a multiplexed way to associate the probe with the response class, and also to physically recover each shape encoded response class for use in subsequent assays.

Sorting assays are novel and useful, since flow cytometers are a powerful technology for reading a reporter, but cannot read shapes, and since they require getting the particles in a fixed position for a relatively long time, in contrast to the microsecond reading time and random particle orientation in flow sorters. It has further been discovered that one can leverage the powerful technology by using it in pure particle sorting mode, then using shape to further decode the results.

A novel enhanced and unique tracer, also designated as a novel enhanced Shape Encoded Particle (SEP) is herein disclosed. The disclosed SEP's are in particular microscopic particles fabricated with specific distinct shapes, whereas these shapes are used as particle identifiers. The shapes are read by assembling the SEP's on a readable support, in particular s surface, and then identifying the shape of the SEP's by using suitable means depending on the support used, e.g., in the case of a flat surface, by taking a micrographic image, which image is then processed by shape analysis software to identify the individual particle shapes shown in the image.

The assembly process can be performed via random deposition of the particles onto the surface, or could include additional positioning aids such as mechanical agitation, vibration, or a specially patterned or sticky surface to facilitate non-overlapping, close packing of the particles for efficient reading. The micrographic images could be taken via optical microscopy, electron microscopy, atomic force microscopy, or any other microscopic imaging technique. In the context of using the particles to perform an assay, probes can typically be coupled to the surface of the particle.

This probe coupling can be done most efficiently on a massive scale by placing a large number of SEP's having given shapes into a single coupling reaction for a given probe. These bulk preparations can then be mixed and aliquoted out into probe sets that represent any number of distinct probes from tens to tens of thousands, each carried by a distinct shape. A set of such probe-carrying SEP's is allowed to react (e.g., hybridize with a fluorescently labeled RNA sample) with the test sample, to cause some measurable change in the associated probe materials.

After this reaction, the SEPs are assembled onto an appropriate surface and imaged to read their shapes. A spatially registered scan of the probe responses is also made. For example, if the probes report via a fluorescent signal, a fluorescent image is acquired, in registration with the shape-decoding image. The fluorescent image may even be used as a shape decoding image. The decoded shapes are associated with the spatially registered probe response signals, thus providing a readout of the probe responses that can be traced back to the respective probes.

Alternatively, the assembly and shape-reading phase could be carried out prior to the assay. In this case, the probe-carrying particles are laid out onto a suitable holding surface, fixed in place, read for shape identity and position, and then used in an assay at a later time held in the same positions, so that only the spatially registered probe response scan needs to be performed at the end. This variation is of value if the assembly or shape-reading require a highly specialized, centralized instrument (e.g. for very close packing or imaging very small shape features) while, on the other hand, the probe response scan uses equipment widely available at end user labs.

The SEP's function most efficiently if close to the ideal of a two-dimensional shape, so that they will lay on the reading surface in a predictable (i.e. “flat”) manner and can have their shape read equally well no matter how they lie and have their shape defined by their boundary curve, reserve most of their interior area for probe carrying, and present the probe on a flat, well-defined face so that the probe measurement scan can also be done accurately, free from artifacts due to variable reading angles.

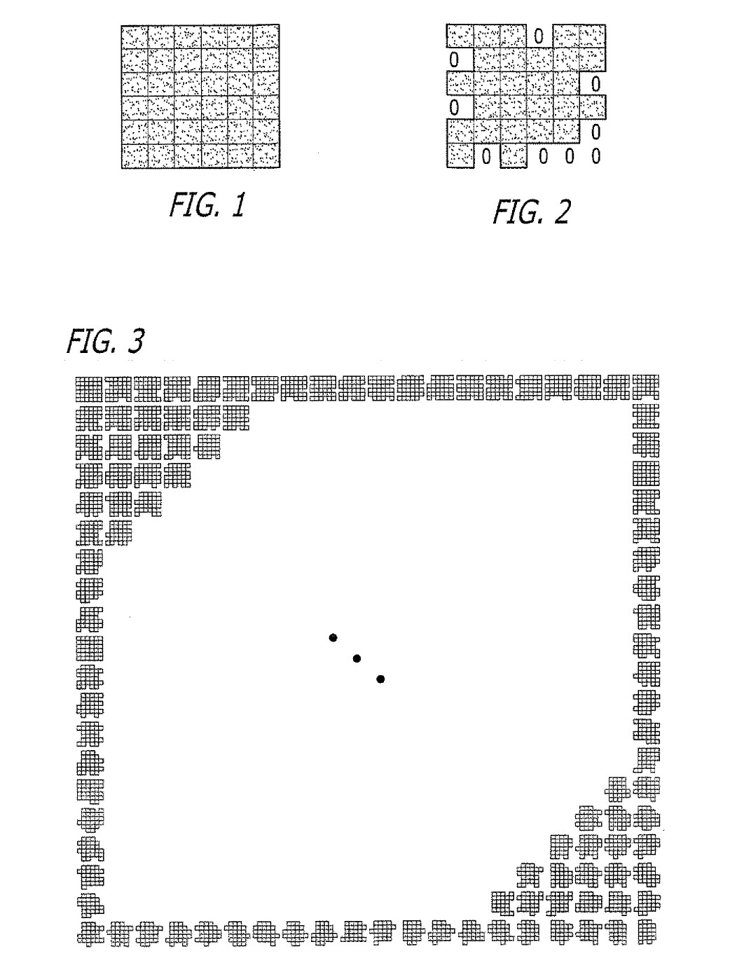

Turning now to FIG. 1, a systematic and efficient way to generate unlimited numbers of distinct, ideal two-dimensional shapes is to start from a basic shape such as a square or circle, and to cut patterns of notches at sites along the boundary (or interior) in a binary fashion (notched or not notched at each site). A special, distinguishable notch can also be cut as an orientation mark, to facilitate orientation of the shape during the image recognition process. SEP's approximating this ideal can be etched from silicon using standard Micro-Electro-Mechanical Systems (MEMS) fabrication techniques.

FIG. 2 shows how the notching binary patterns on the edge of a base shape can work. In the illustrated example, notching binary patterns in the edge of a squared-type of base shape provides for later bit-mapping. In the schematic shown, for example, a binary ‘name’ of a shape is assigned—in this case 11101110100001011010.

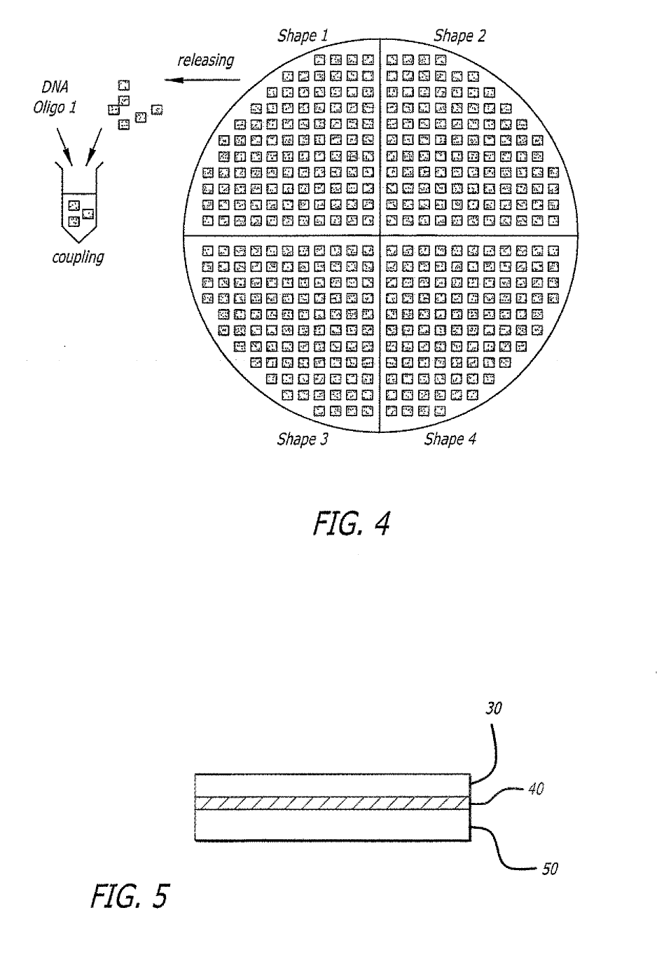

Those skilled in the art understand that since the number of distinct shapes grows exponentially with the number of notch sites the number of molecules or materials that can be uniquely labeled is practically unlimited. FIG. 3 illustrates this by showing that for N sites there are 2ⁿ shapes, or that with 20 sites there will be approximately 1,000,000 shapes. In the view which is sampled, silicon wafer squares having 6 notches per side would generate 512,000 possible variants (the sample is taken from a 400 choice random view). FIG. 4 shows a schematic step wise depiction of SEP's used for shaped encoding a possible number of DNA k-mers whereby a many distinct particles are cut, and after K steps of mix-split-extend randomly synthesized DNA k-mers use the (4×K) images to trace for each shape which K extensions it underwent and this the k-mer attachment. Artisans will understand how this works in the context of building blocks.

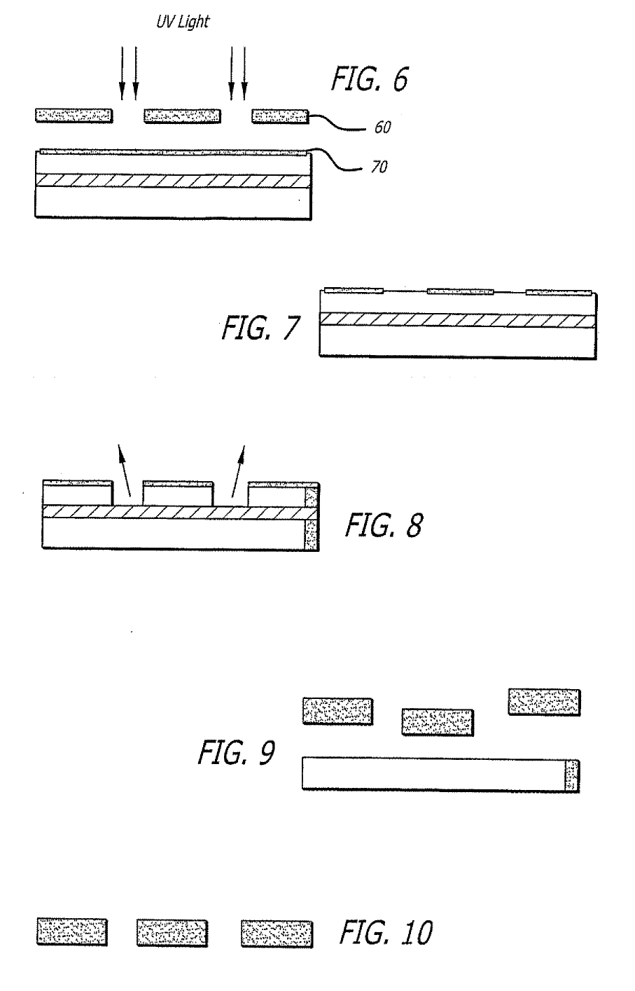

FIG. 5 through FIG. 10 schematically illustrate a process for shape fabrication, according to the present disclosure. Turning to FIG. 5, a silicon wafer is fabricated in which a polycrystalline is layer of micron-scale thickness (eg. 10 microns) sits on a dissolvable SiO₂ layer (eg. 2 microns), and photolithography (FIG. 6 , FIG. 7) and reactive ion etching (FIG. 8) is used to etch the shape outlines into the Si layer. The shapes are then released by dissolving the underlying SiO₂ layer with HF acid (FIG. 9 FIG. 10). In this way. SEPs with a thickness in the 1-50 micron range and diameter in the 10-300 micron range can be readily fabricated, with a capacity for millions of distinct shapes at any given size in this range, readable with standard optical imaging systems (such as those commonly used for microarray slides). Over one million such particles could fit into a standard assay reaction carried out at a typical volume of 10-100 microliters. Biological and chemical probes can be attached to the resulting silicon surface by a combination of heavily oxidizing the surface to a glass-like state, and using standard attachment processes for glass surfaces.

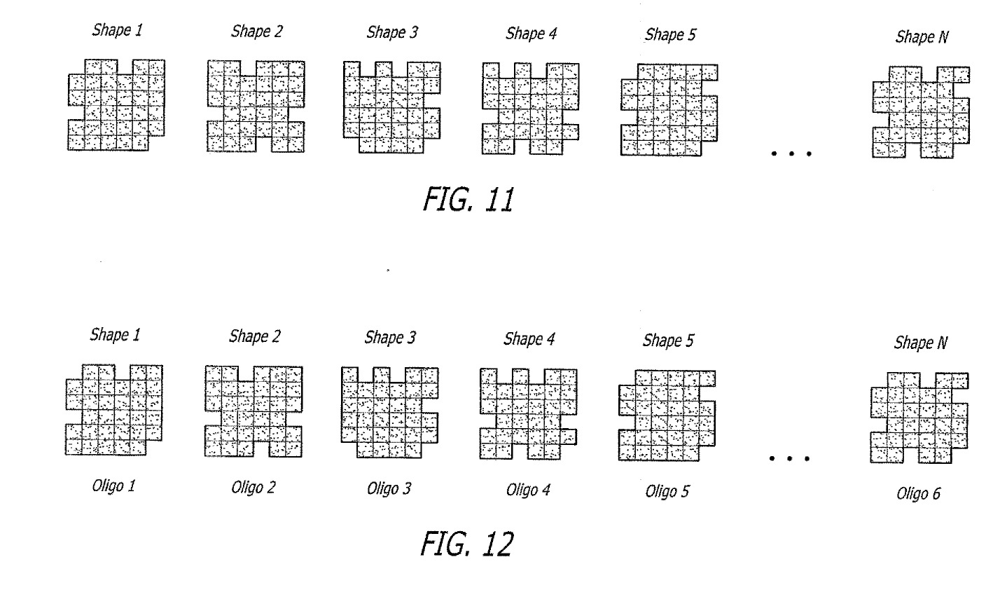

Turning now to FIG. 11 and FIG. 12, manufacture of SEP's is shown in a progression from shape 1 to shape N. According to the instant teachings, the coupling of the probe (for example the Oligo shown in this figures set) to the SEP is done in separate tubes and then all of the SEP's are mixed in a tube and a portion taken for each hybridization. At present, among the most important probes are DNA probes for use in gene expression assays or polymorphism detection assays. For applications such as where a DNA oligo probe is appropriate, the ago synthesis can be done directly on the silicon particles using standard, highly efficient oligo synthesis techniques, bypassing the need to separately synthesize and attach the oligo. Alternatively, oligonucleotide probes or protein probes can be synthesized first and subsequently attached to the SEP's via attachment to the silicon surface.

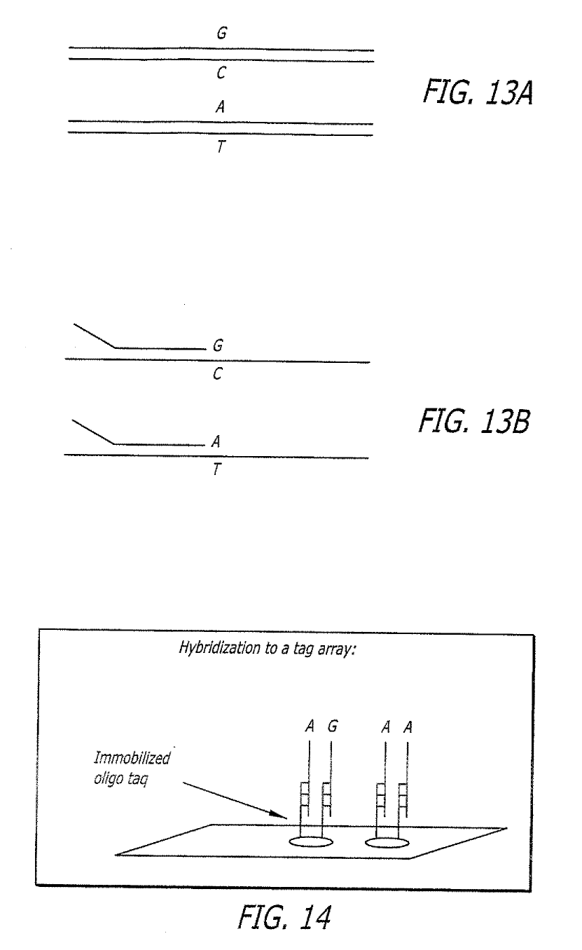

FIG. 13A shows a first step in genotyping with single base extensions and SEP's according to the instant disclosure, whereby a PCR reaction is run. In FIG. 13B single base extension is illustrated with Cy5-ddGTP/Cy5-ddATP. Shown is an anti-tag and SBE primer, while FIG. 14 shows hybridization to a tag array. Hybridization to the SEP follows whereby the respective flakes are coupled to individuated oligo tags.

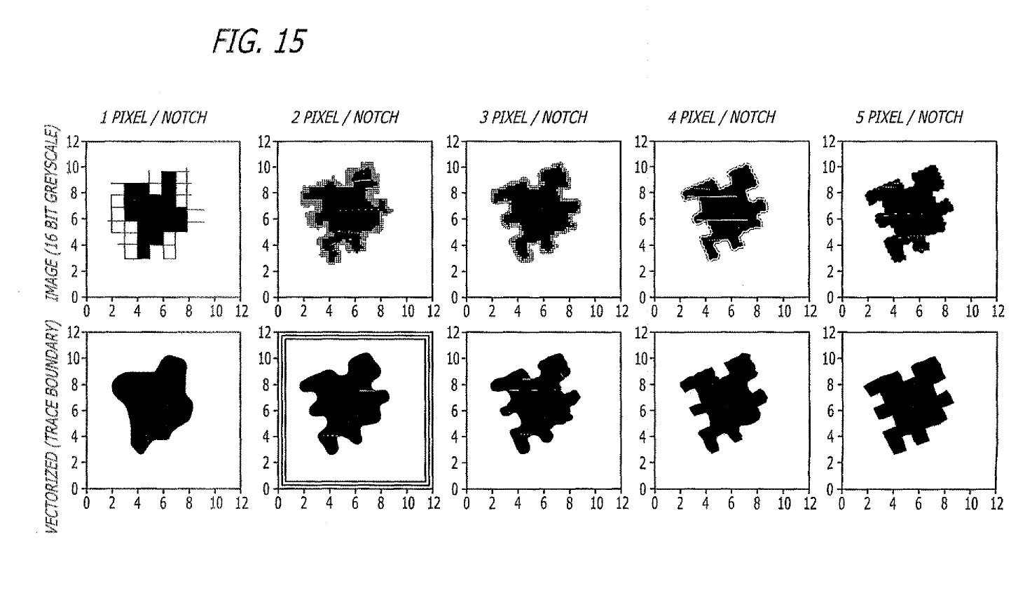

Turning now to FIG. 15, the method whereby isolated images are readable is shown, and the figure set is demonstrative of a boundary curve traced from the original image become readable at resolution of 2 image pixels per notch. Physical size limitations for optical imaging are gauged at 1 pixel˜1 micron with a 6 notch/side shape relating to 12 microns per side and 1,00,000 shapes/square cm.

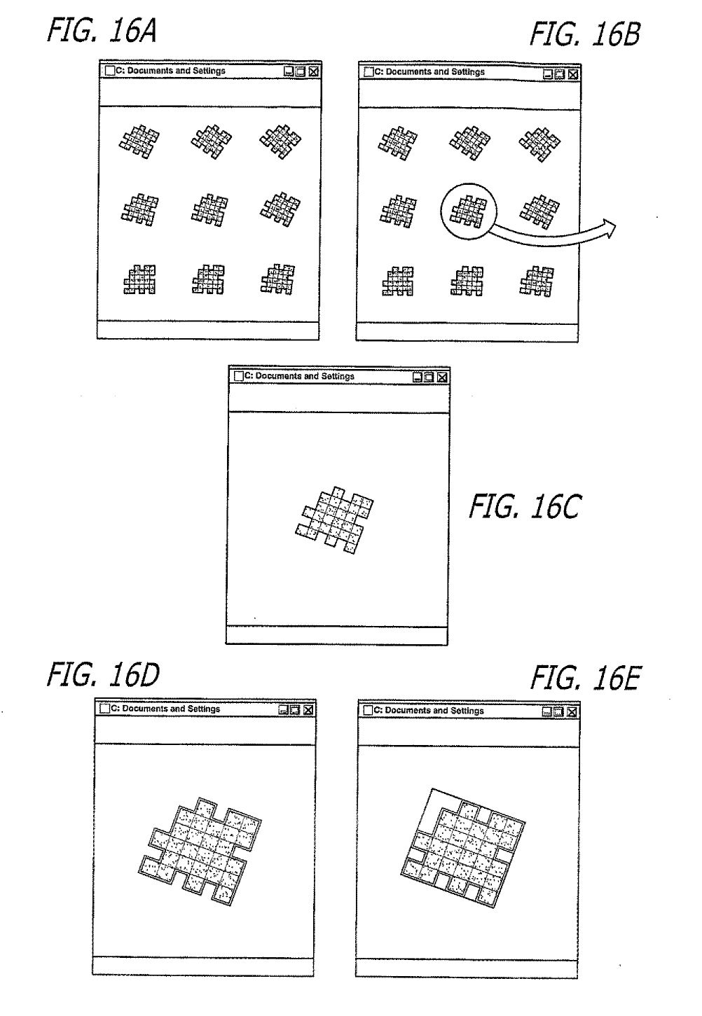

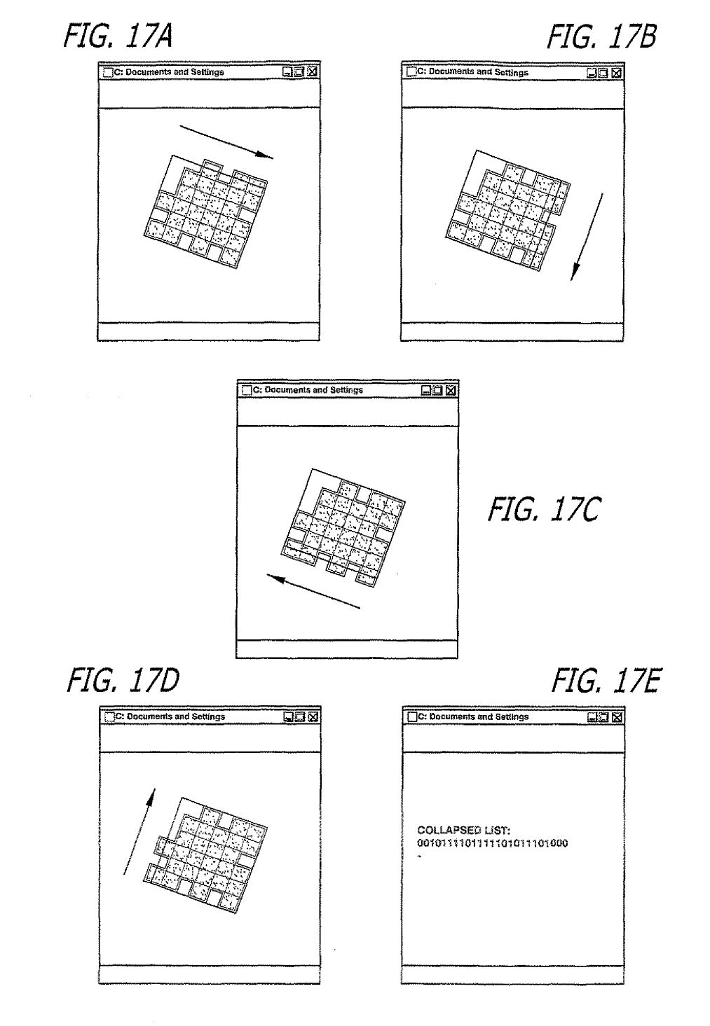

FIG. 16-FIG. 17 show the operation of ShapeReader™ type of software which implements the algorithms of the present disclosure by providing a user interface consisting of pull-down menus, check-boxes, numerical input forms and file selectors for specifying the inputs. FIG. 16A takes an original complex .TIF image, FIG. 16B locates the isolated features, FIG. 16C shows the cut out of each feature for analysis, FIG. 16D tracing boundary curves from the images, 16E fitting of the ideal base shape to the boundary. FIG. 17A shows reading of the edges by moving in ½ notch, reading 1^{st} edge, 17B the 2^{nd} edge, 17C the third edge and then the last edge. FIG. 17E shows converted edge reads into decoded binary shape name (see FIG. 2, and the discussion regarding the same.)

In practice, the software displays each original shape decoding image in a separate window, and also displays the cleaned up and segmented form of the image, with segments indicated visually by distinct colors; then in real time it produces a spreadsheet-style layout, line by line, where each row is data for a different particle, consisting of all the relevant images and alphanumeric data; specifically, each row contains a series of fields which show a portion of the original image including the particle, the resulting ideal shape fit to this image segment, the shape decoded ID, the decoding uncertainty, the associated probe ID, and the reporter signals and their uncertainties, and false color image segments from the various reporter images, as well as a composite false color image of all reporter signals and the shape image; data from multiple shape decoding images specified at the input are assembled into a single such sheet; the resulting image/data spreadsheet can be sorted by any of the quantitative measures (signals or uncertainties), or by the shape codes, and it also provides an inspector selection mode which can be used to examine the image data of a given row in magnified detail, and to make manual edits to the shape determination or signal determination in this mode, which are subsequently updated into the sheet. The software stores this output sheet in a database, which can be subsequently recalled in this graphical format, and can also export a table containing just the shape code, probe ID and quantitative data.

It has likewise been discovered that SEP's may so be used as a tracer for bulk materials, in order to trace their point of production, or subsequent mixing, distribution, handling, sales, redistribution, ownership or authenticity. For this application, each material to be traced is embedded with many copies of a unique, microscopic shape encoded particle, either by mixing the shape internally with the material, or applied it to solid surfaces. At any point of identification, shapes are exposed on or recovered from the material, and imaged to establish the shape and thus identity. The advantages of this method of identification are that it is physically attached to the material and distributed throughout the material, so it is robust, persistent, un-erasable and holographic (i.e. can be read from an arbitrarily small sample).

All major aspects of the instant disclosure have undergone at least preliminary testing. Specifically, SEP's (50-300 microns along an edge) have been etched from silicon wafers in the form of square shapes with notched edges. The shapes have been coupled to DNA oligo probes and hybridized to fluorescently labeled reaction products normally read by hybridization to a DNA microarray. They have been randomly deposited onto a microscope slide for reading images using white light and fluorescent light microarray scanners and the images analyzed using software developed by the inventors to segment out and decode the shapes. In addition, computer simulation studies have been undertaken by the inventors to optimize shape design and decoding, and to optimize the random assembly procedure.

The tracer assembly and the relevant process of manufacture herein disclosed provide a way to create an arbitrarily large number of distinguishable microscopic particles. These particles are to be used as tracers for distinct biological or chemical molecules, in particular probes used in assay. In such cases the tracer can be used as a probe-bearing carrier. Many components of a complex test sample (such as an RNA extract from cells or tissue) can be assayed simultaneously by a mixture of many such probe-bearing carriers, with the test results sorted out and associated back to the specific probes by using the carrier particle identity as the key.

The utility is similar to physical DNA or oligonucleotide microarrays, which are widely used to assess thousands of gene expression levels simultaneously, but allows more flexibility in experimental design, can greatly simplify the experimental procedure, and can greatly improve the efficiency and quaky of the manufacturing process.

A first advantage of the tracer, assembly, processes, methods and kits herein disclosed is that they provide a system that allows for the low cost production of an arbitrarily large number of distinguishable, universal probe carriers, which can fit conveniently into standard assay reaction volumes and which can be read in an automated, massively parallel fashion. In particular, an advantage over the traditional microtiter well plate format is that the tracer and assembly disclosed herein allow many probes to be multiplexed in a single, small reaction volume and read in a massively parallel fashion. Thus, the approach greatly reduces the amount of reagents and sample material consumed and the amount of liquid transfer and sample handling required to assay against a large number of probes.

A further advantage over the microarray format of the tracer and assembly herein disclosed is that of avoiding the various complexities of array printing or fabrication. In particular, the format developed by the inventors is better suited to large scale production, since probes can easily be coupled to shapes in bulk. However the tracer and assembly can be used in a microarray assay. Also, another advantage over the existing prior art is that the format provided in the disclosure is completely flexible, so that probe sets can be subselected or extended without the need to “reprint” an array, thus allowing for completely customizable probe sets at no extra fabrication cost.

A further advantage over the existing prior art is that with the tracer and assembly disclosed herein it is possible to carry diverse probe materials and use diverse probe-to-particle coupling reactions. On the other hand, the Affymetrix light directed microarray synthesis process, for example, is limited to producing short DNA oligos (and perhaps short peptide chains) as probes, and pin based or ink-jet based printers are mechanically limited in the range of probe materials they can print. The assay reaction can be also carried out in a smaller volume and with better mixing than microarrays, since the probes according to the disclosure are not constrained to a relatively large (X,Y) surface during the reaction.

Another advantage over the various labeled microsphere approaches is also that the method of shape encoding developed by the inventors produces a uniformly easy to fabricate, low cost, unlimited supply of distinguishable particles. However, dye labeling or oligo labeling becomes progressively more complex and costly to fabricate and to decode as more labels are required. Also, dye labeling may interfere with the fluorescent dyes commonly used as probe reporter signals, and DNA oligo labeling may interfere with the DNA probe hybridization process which is frequently the primary assay reaction. In contrast, the shape encoding according to the disclosure cannot possibly interfere with the probe reporter signals or probe-sample reactions.

The tracer and/or assembly herein disclosed may also advantageously be used in the deployment of a large scale set of DNA probes for gene expression analysis, polymorphism detection or other applications commonly associated with DNA microarrays, both for the technical merits described and to be free of restrictions that accompany the microarray format.

Additionally, the tracer and/or assembly herein disclosed can be used as a universal probe carrier system that can handle a diverse set of probes including DNA oligos, cDNA fragments, antibodies, proteins, whole cells, cell membranes, or other biological and chemical probes yet to be determined. This is because of the unique combination of generality, low cost, flexibility and scalability of tracers assembly kits and methods herein disclosed.

Further, with the readily feasible highest density SEPs multiplexing and the use of conventional microarray scanners, about 32,000 individual assays can be simultaneously measured. This is on the same scale (21,000) of the highest density DNA/oligo arrays for gene expression measurement which currently typically costs $200-1000 for each array. The SEPs based multiplexed analysis can be performed for an order of magnitude less, at present materials costs, while allowing each gene expression value to be sampled on average 10 times for clarity of signal.

Further details concerning the molecules, probes, reagents, concentrations, formulations, vehicles, carriers, auxiliary agents can be identified by the person skilled in the art, upon reading of the present disclosure. The following examples are provided to describe the invention in further detail. These examples, which set forth a plurality of preferred modes presently contemplated for carrying out the invention, are intended to illustrate and not to limit the invention.

The disclosures of each and every publication and reference cited herein are hereby incorporated by reference in their entirety, in the present disclosure.

To better explain the difference between the prior art, the state of the art and the present disclosure the following examples are offered for consideration. Those of normal skill in the art will understand this discussion informs and enables the claims appended hereto and is intended to be illustrative and not limiting.

### EXAMPLES

Those skilled in the art understand that because shape encoded particles provide a general method of assigning identity that is of unlimited capacity, highly multiplexable, microscopic and robust, the current disclosure also has many potential applications to identification, tracking and authentication of materials, as discussed within the instant disclosure and claimed below.

It is important to understand that tracking the original motivation for the current disclosure, for example, that an alternative was needed for the microarray format for biological assays, informs and enables this other promising applications and areas in which the novel enhanced SEP's have functional utility.

The present inventors likewise contemplate using the shapes to carry biological probes that engage in a binding reaction with a sample, and report via a fluorescent signal to be read using an optical microscope imaging system.

### Example 1

### Parallel Handling of Shape Encoded Particles for Massively Multiplexed Assays

In doing a multiplexed assay as above, a special set of parallel handling procedures that maintain high throughput is employed. Each distinct shape is fabricated in bulk quantities, undergoes a attachment reaction to form a shape-probe conjugate, and all these preparations are pooled these to form a master mixture of encoded probes. This mixture is dispensing in (randomly sampled) aliquots of complete probe sets to perform individual, and the results of each assay are read with an automated imaging system and shape recognition software. According to the present disclosure there is shown this emphasizes a unique way to maintain a high degree of parallel handling of the particles through fabrication, probe-attachment, and reading, in contrast to ever handling the particles individually.

Likewise disclosed is a method for massively multiplexing assays which is not constrained by space limitations and does not restrict spatial mixing during reactions, probe reporter spectrum, or probe chemical environment. In the assays as above, the probe-particles require extremely amounts of macroscopic volume or area, all spatial dimensions (x,y,z) are free to be used for bulk mixing of probes with the sample during reactions, all the color/electromagnetic spectrum is free to be used for the reporter signal, and the immediate chemical environment of the probe is free to be optimized for probe attachment and function.

It is noted that this set of examples underscores the unique merits of shape encoding relative to other existing methods of multiplexing probes. Existing methods typically constrain space (microarrays, probes not free to move/mix in x-y space), constrain the allowed reporter signal color spectrum (color encoded plastic beads of Luminex, Inc, or glass barcode glass beads of Corning, Inc, or gold/silver banded metal beads of Nanobarcode, Inc.), or the chemical encoding of beads (e.g. by attaching DNA tags to surface, of Illumina, Inc.) which restricts the allowable chemistries and reactions that the bead-probes can be exposed to during attachment or assays, and partially consumes the chemical binding sites of the bead surface that would otherwise be used for probe attachment or assay optimization.

### Example 2

### A Method of Encoding Particles that Allows Recognition by One-Bit Imaging

The present inventors disclose a process using SEP's robust enough to manufacture via etching, that maximizes particle encoding capacity while preserving a special free region optimal for probe attachment/detection, and that reduces the chances of engraved features “clogging” with debris. In addressing these longstanding needs a preferred form of shape encoding or particle identification is disclosed according to the instant teachings. If the goal is to image using a one-bit (“black and white”) image system (=simple and robust for recognition) and do robust etching (=simply cut all the way through, which is robust to do and image, versus an etched serial number or mark, which is harder to control and image), and preserve viewable area for the probe but maximizes the coding capacity (=make particle fiat, and put the etched features on the edge where there is most room, reserve interior for probe attachment only), and make notches along the edge instead of holes (less likely to clog, takes less area for notches than for holes), one arrives at the notched flat particle design favored for shape encoding.

### Example 3

### Shape Encoded Particles for Tracking the Identity of Reporter Probes in a Massively Multiplexed Reporter Assay

The present disclosure further contemplates specialization of the type of assay, if such is needed. The present teachings are directed to reporter assays, in which a probe material is bound to the particles, the assay modifies the state of the bound probe material, and this modification is registered by a detectable reporter. This covers not only binding assays, where the state modification is binding to a target, but also enzyme activity assays, where the assay looks to see if an enzyme modifies a substrate, or proliferation assays, where the assays looks at whether cells replicate or die, etc.

### Example 4

### Shape Encoded Particles for Tracking the Identity of Binding Reaction Probes in a Massively Multiplexed Binding Assay

What is disclosed is a further specialization of the type of assay, if such is needed. It still covers the great majority of practical applications, as one is usually concerned with (broadly) binding-type assays, where the probe on the particle binds to a target in the sample, and either the target is labeled with a reporter, or the bound complex itself triggers a reporter, for example by quenching an emission. More general assays can also often be converted to this form, as well.

### Example 5

### A Systematic Design for Sets of Shape Encoded Particles that Allows for Arbitrarily Large Capacity and Unambiguous Multiplexed Decoding

The general design is as a thin, flat particle, consisting of a base shape (such as a square), augmented by systematic notch patterns along the edge. The encoding capacity of the set is adjustable, since the number of independent notches along the edge controls the encoding capacity, with N notches encodes for 2^{N} shapes. These are typically not all distinguishable in a multiplex reaction, since they may land in any orientation (rotated or flipped). In order to remove this potential ambiguity, the base shape may include an orientation mark for unambiguous interpretation, or the set can be restricted to the subset of shapes that are not related by any rotation or flipping symmetries.

According to the present disclosure, a tested and proven form is a notched square, with greater than a 4:1 width:thickness ratio to ensure that it will land and lay flat, under the influence of gravity or centrifugation.

### Example 6

### An Algorithm for Generating Systematic Families of Shapes of Unlimited Encoding Capacity

Systematic notch patterns, used in conjunction with the instant teachings may be further defined as follows:
i. given a code word consisting of N digits in base k,

C=(c₁, c₂, . . . , c_{N}),
ii. where c₁ε[0,1], . . . , k−1} (e.g., k=2 is binary code, each cᵢ is 0 or 1), we associate it with a 2-dimensional closed curve S[C]—the “shape”—defined by the “notching equation”

S[C](t)=b₀(t)+c₁b₁(t)+c₂b₂(t)+ . . . +c_{N}b_{N}(t) iii.

where t ε [0,1] is a parameterization of the base shape boundary curve. Here, b₀(t) represents the equation of the base shape boundary, and the other bᵢ(t) represent the equations of the basis of curves corresponding to the distinct potential “notches”. The number of distinct code words, C, is k^{N} (2^{N} for binary coding). However, the corresponding 2^{N} shapes cannot all be used in the encoding family, since they must satisfy two restrictions: they must be “distinguishable in any orientation”, i.e. any two shapes must be distinct under all rotations and flips, and they must be “manufacturable”, meaning that if the shape was cut from a material sheet, it would not have any dangling or disjoint parts (or, mathematically, the image of S[C] is the boundary of a connected open set). Any subset of shapes satisfying these constraints forms a viable family.

### Example 7

### Shape Encoding Using a “Positional Notching” Design

A special case of the above, in which the perturbing basis bᵢ(t) correspond to isolated notches or bumps (rectangular or smooth) positioned around the edge of the base shape. The base shape may include a special orientation mark. Typically the base shape is a large square, with completely disjoint small square notches along the edge, done in a binary Notched-or-Not-Notched” format.

### Example 8

### Shape Encoding Using a “Frequency Notching” Design

A special case of the above, in which the perturbing basis bᵢ(t) correspond to distinct frequencies of sinusoidal ripples (mathematically, distinct Fourier Modes) along the boundary of a circular base shape. In this case, the “notching patterns” overlap in space, and the resulting shapes look like complicated images of a vibrating loop. These curvy shapes would be more difficult to manufacture in practice, but the attraction is that the powerful and well-developed methods of “Fourier Analysis” (sorting out complex wave patterns into component frequencies) could be used in the image processing, recognition and decoding algorithms.

### Example 9

### Shape Encoding Using a “Wavelet Notching” Design

A special case of the above, in which the perturbing basis bᵢ(t) correspond to the first N modes of a “wavelet” basis (positional frequencies with specific mathematical properties) for curves along the base shape perimeter. This is a hybrid of frequency notching and positional notching, using a mathematical construct called a “Wavelet”, which is a ripple that is localized in space in a systematic way that aids decoding. Again this would only be attractive because well-developed Wavelet Analysis techniques could be used in the recognition algorithms.

### Example 10

### Shape Encoding Using a “Fractal Notching” Design

This is an extension of the above general encoding strategy, in which we iterate the basic procedure, notching finer notch patterns on top of coarser notch patterns, thus generating notches on finer and finer resolution scales. This results in a frilly “snow-flake-like” shape design, more properly called a fractal or multiresolution curve. Specifically, the master family of shapes is generated as follows: given any series of M base k code words of the type above, X={C₁, . . . , Cᵢ, . . . , C_{M}}, the single shape defined by this entire series, S[X], is defined iteratively as follows: the first iteration, S[C₁], is defined as usual above, relative to some base shape. Then, given an iteration S[Cᵢ], the next iteration is defined by:

S[Cᵢ₊₁](t)=S[Cᵢ](t)+cⁱ₁bⁱ₁(t)+cⁱ₂bⁱ₂(t)+ . . . +cⁱ_{Ni}bⁱ_{Ni}(t) i.

Where S[Cᵢ] plays the role of the base shape for this step, and bⁱₘ is a basis of perturbations along this new base shape. These will typically be a reduced scale form of the type of notches used on the coarsest scale. The final or limiting shape produced by this process, S[C_{M}], is the shape S[X]. The number of encoding shapes described this way is the number of encoding vectors, X, which is k^{N}, where N is now the total number of encoding digits in X, N=N₁+N₂+ . . . +N_{M}. This master set of shapes is subject to the same distinguishability and manufacturability restrictions as before to produce viable encoding families.

### Example 11

### A Concise, Scalable and General Shape Specification Language

Within any of the above schemas for designing shapes, a specific shape can be specified completely by giving a definite size for the base shape, and then the list of basis coefficients (c1, c2, . . . , cn) used in the above formula that generates the shape. Thus this code (c1, c2, . . . , cn) provides a concise language for describing the shapes, for the purposes of describing the shapes during encoding, decoding, automated mask design, etc.

### Example 12

### Photolithography Masks for High Density Fabrication of Shape Encoded Particles

A photolithography mask designed as follows: A standard polygon is chosen which would enclose any of the desired shapes, for example a square 100 microns on a side. The standard polygon is replicated many times, in a high density, closely spaced regular array, or an array of regular subarrays with a margin separating the subarrays, that covers the available mask area with N polygons. These polygon positions define the available shape locations on the mask. Then, given a set of N desired shapes (which may be distinct, or may include replicates), these are used to populate the available locations on the mask. In the common case where a small number of distinct shapes is being fabricated in replicate, the N shapes consist of D distinct shapes, each with c=N/D replicates, the layout consists of D subarrays of size c, and each subarray will be populated by a distinct shape, replicated c times. The margin between the subarrays is of sufficient width to allow mechanical separation of the subarrays after etching. The above design process is preferably implemented in software which takes as input the mask size, the standard polygon size, the specification listing of the desired N shapes (either as an explicit list of N shape descriptions, or as an explicit list of the D distinct shapes, using the above shape specification language, and the desired level of replication), translates the shape descriptions into admissible mask pattern specifications (satisfying any restrictions on feature width, line angles, etc) and automatically produces as output the mask specification file suitable for reading by the pattern generator system used to fabricate the mask.

### Example 13

### A Parallel Method for Producing a Precisely Specified Pool of N Shape Encoded Particles

The N desired shapes are put on a mask for a single wafer, the wafer is etched, and the entire set of shapes is released and collected into a single pool. In cases where N does not match the capacity of one wafer, the procedure can be spread across multiple wafers, or a subsection of a single wafer. Here, in particular, the N shapes may consist of a single representative from N distinct shape types, so that we guarantee exactly one of each type.

### Example 14

### A Shape Encoded Process Diagnostic Mask Design

This is a special mask used to diagnose the fabrication process itself, in which the possible x-y locations of shapes on the mask are all uniquely encoded using distinct shapes. Thus shapes can be traced back to their position on the mask, and this can be used to identify positional artifacts of the manufacturing process, such a poor etching quality near the edges of the mask, regions prone to contamination or damage during wafer handling/cutting, or regions that do not perform well during releasing steps.

### Example 15

### Variable Encoding Capacity Mask Designs

Mask designs containing multiple shapes, specially organized in such a way that the pattern can be progressively divided with a series of cuts into greater numbers of completely disjoint shape code sets. This is achieved by locating distinct shapes in distinct regions, with the regions defined by a hierarchical progression of straight cuts. For example, binary subdivision: on wafer surface described with rectangular x-y coordinates, consider a series of cuts that first divide x in half, and then the halves in halves again, etc, for k halvings, using N=2^{k-1} cuts, and similarly subdivide the y direction. Then the N×N cuts generate N² subregions, each of which can have with it a single shape or distinct set of shapes, all distinct from other regions. Sufficient spacing is left between the regions to make physical cuts in the etched wafer, if desired. From a wafer etched with this pattern, all shapes can be collected in a single pool, or it can be divided into halves, fourths, sixths, eights, generating between 1 and N² distinct shape code sets (which may be individual shape types or disjoint mixtures of shape types). According to the inventors this allows “variable capacity” mask designs, which contain a reserve of many more shape types than may desired in any particular application. This can be used to save costs on mask generation, since each single mask can be used to generate a variable number of disjoint code sets, ranging anywhere from one single pool (useful for assay development, where encoding multiple probes is not essential) to the number of shape types present on the mask.

### Example 16

### Variable Capacity Mask Designs Correlated with Shape Decoding Properties such as Parity or Resolution

The spatial layout may be correlated with properties of the shape codes in the layout, allowing convenient subselection of shape classes with special properties, for improved handling purposes, or for tracing of particle type back to mask location, for quality control of the fabrication process. Example 1: shapes with even/odd numbers of notches could be placed on the upper/lower half of the mask, so that the notch “parity” is correlated to the first major cut. Additional levels of parity (e.g. parity along different sides of the shapes, or k-parity=remainder of 0, 1, . . . , k−1 upon division by a k) could be determined by successive cuts. Thus shape parity is determined by the series of cuts, and can either be used to check for handling errors (parity checking=compare expected parity against observed parity) or to obtain encoding sets that can be more easily described (even vs. odd number of notches, or other parity counts). Example 2: fractal shape designs, layed out so that finer subdivisions return shapes coded on a finer scale and thus requiring a higher resolution imaging system for decoding. In this approach, a coarse subdivision of the mask would yield shape sets distinguishable on a coarse imaging system, and as greater imaging resolution is available, more finely divided sets of shapes could be recovered using the same underlying mask. Inherent benefits of this approach include industrial efficiency and more convenient, reliable or customizable handling of sets of shapes.

### Example 17

### Variable Capacity Mask Correlated with Shape Decoding Properties

Likewise, the spatial layout may be correlated with specific properties of the shape codes in the layout, allowing convenient subselection of shape classes with special properties, for improved handling capabilities. According to the present inventors this may allow more convenient, robust or reliable handling of sets of shapes.

### Example 18

### Variable Capacity Mask Designs Correlated with Notch Parity

A special case of the above, where location on the mask determines various parity subclasses of shapes, to be used in parity checking error detection, or parity-based decoding algorithms. For example, shapes with even/odd numbers of notches could be placed on the upper/lower half of the mask, so that the notch “parity” is correlated to the first major cut. Extending this concept, additional forms of parity (e.g. notch parity along different sides of the shapes, or notch “k-parity”=remainder of 0, 1, . . . , k−1 upon division by k) could be determined by successive cuts. Thus a general parity class is determined by the series of cuts defining the shape class. This prior parity knowledge can be used to check for various types of errors in subsequent handling or decoding procedures, or to design more efficient decoding procedures.

### Example 19

### Variable Capacity Mask Designs Correlated with Feature Resolution

A special case of the above, where fractal shape designs are used, with a layout such that finer subdivisions return shapes that are distinct when resolved on a finer scale. In this approach, a coarse subdivision of the mask would yield shape classes distinguishable on a coarse imaging system, while finer subdivisions would yield distinct classes, but only when imaged on a finer scale. For example, perhaps dividing the wafer into 1, 4, 16 or 64 subgroups of shapes results in distinct shape classes readable at 10, 5, 2, or 1-micron resolution. Thus again a single mask produces particle for a variety of imaging system resolutions, but without wasting any particles at any given resolution.

### Example 20

### Fabrication of Shape Encoded Particles by Reactive Ion Etching of Silicon-On-Insulator Wafers

A photolithographic mask defining the particle shapes is produced as described in previous claims. The mask is used to perform Reactive-Ion-Etching of a Silicon-On-Insulator wafer, consisting of poly-crystalline silicon on a SiO₂ substrate. The thickness of the crystalline layer is chosen to be that of the desired particles. Reactive Ion Etching is performed, for sufficient time to cut through to the substrate. The etched wafer may then be subdivided (using a diamond saw, or by scoring and fracturing along crystalline directions) into subsections for separate subsequent handling. For each resulting piece of the wafer, the etched poly-crystalline silicon is then physically released by dissolving the SiO₂ substrate with a hydrofluoric acid treatment, resulting in a pool of free particles. The freed particles undergo surface oxidation reactions, either via heating or by a hydrogen peroxide treatment, to prepare them for subsequent handling. Finished particles are stored in pure H₂O. The present inventors have discovered that with the protocol employed works with conventional MEMS technologies, but yields unexpectedly better results.

### Example 21

### Altered Surfaces for Silicon Shape Encoded Particles

Increases in surface area, roughness, or porosity may improve probe attachment or function. Possibilities unique to etching of Silicon include roughening, or creating porous or corrugated surface. Also, for many purposes the surface must be heavily oxidized, as well, which can be done via post treatment with heat in an oxygen rich atmosphere or with reaction against hydrogen peroxide.

### Example 22

### Shape Encoded Particles as Multiplex Carriers of Porous Silicon Probes

Porous silicon is known to act as a probe for chemical concentrations, in the sense that when it is exposed to a solution, chemicals in solution can bind and alter the optical properties of the pores, changing the spectrum of reflected light in a characteristic way. Thus the optical reflection spectrum of the porous silicon becomes a reporter for the chemical composition of a test sample. The reporter properties of the porous silicon probe depend on the details of the porosity, such as pore size, pore density and pore spatial patterns. Silicon shape encoded particles can act an ideal “carrier” for such porous silicon “probes”, simply by giving the particle the desired level of porosity. This can be done, for example, by using controlled ion bombardment or other standard means of making silicon surface porous, in the course of fabricating the shape encoded particle, such as before or after etching of a Silicon-On-Insulator wafer, or by growing a special layer of porous silicon on such a wafer substrate. Distinct shape encoded particles can carry distinct levels of porosity, identified by the shape, so that such probes can then be multiplexed in assays. The reader system for this reporter either uses a spectral imager to record the full reflection spectrum of the reacted particles, or uses one or more optical filters to record the spectrum in a specific set of wavelength channels sufficient to characterize a particular type of concentration measurement, which may be done at a lower resolution than that used for the high-contrast monochrome image taken for shape identification.

### Example 23

### Shape Encoded Particle Silicon Porosity Spectral Response Assay

In the course of developing a porous silicon probe for a particular chemical compound under particular conditions, it is necessary to expose many different levels of porosity (pore size, pore density, pore patterning, etc) to many samples, to characterize the spectral responses and to find particularly sensitive porous probes. For this purpose, pattern or grid of different surface porosities is created on a Silicon wafer surface, and the wafer is subsequently cut into shape encoded particles, in such a way the different porosities are encoded in a known way by the shapes. The resulting particles are pooled and used in an assay against a sample. This results in a massively parallel characterization of the responses of the different porosities. Further, if the goal is only screen for a desired strong response, in order to find optimal probe porosity, strong response particles can be rapidly and efficiently sorted out using a flow cytometer cell sorter, and the chosen particles can have their porosity identified by shape decoding. This assay can be further multiplexed across many different concentrations or conditions for the sample, by using a distinct set of shape codes for each such sample, then pooling all particles after independent reactions with the respective sample, and then reading or sorting as before, but now the shape code in the final reading identifies both the porosity and the concentration or sample condition.

### Example 24

### A System for Multiplexed Shape Encoded Porous Silicon Probe Assays

Silicon wafer layouts for shape encoded particles and layouts of surface porosity treatments are coordinated on one or more wafers, so that in total, each of P different porosity conditions overlay onto a regions containing D distinct shapes in R-fold replicates. The surface porosities are created, and the particles cut, and products from all such wafers all are pooled, to form a master assay pool that contains the P different porosity probes, each in R-fold replicate on a total of N=P*R*D particles. This pool can be used as a single assay, or can be aliquoted out for M assays, in which we statistically expect RIM-fold replicates of each porosity probe. In particular, the resulting assay set or sets are generated in a parallel fashion, without ever physically isolating the individual porosity probes, which is a novel feature of the above system. The present inventors understand that the fact that an entire assay is created just through silicon fabrication techniques is quite attractive, and potentially very efficient, especially if the porosity treatments can be done in an efficient way.

### Example 25

### Shape Encoded Particle Fabrication by Casting from Molds

Shape encoded particles are fabricated using a massively parallel casting mold. Such a mold consists of two rigid flat plates. On the “lower” plate is a closely spaced array of precise depressions that define the desired particle shapes. The upper piece consists of a perfectly flat plate. The casting material, which may be a liquid or semi-solid precursor of a glass, ceramic, plastic, polymer matrix or metal, is spread between the plates, which are then forced together to force the material into the depressions. The material is then allowed to harden, after which time the particles are released from the mold. Methods to eliminate trapped air bubbles may be employed, such as performing the process under vacuum conditions, or using air-permeable or perforated plates to allow the release of trapped air. The lower plate may also contain grooves or channels on its surface, between the shape molds, that facilitate the escape of excess air or casting materials. The casting plates themselves may be made by lithographic methods to precisely etch a hard material such as silicon, quartz, or metal, or may be caste metal plates.

### Example 26

### Shape Encoded Particle Fabrication by Slicing Bundles of Shaped Filaments

A method in which fine filaments are created with cross sections in the desired shapes, and the filaments are formed into a bundle, which is finely sliced to release pools of shape encoded particles. If the bundle cross section consists of N filaments, each slice will produce a pool of N particles. The filaments in such a bundle may all have the same cross section, thus creating a single type of shaped particle, or a variety of distinct cross sections, thus creating distinct shape types. One method for forming such a bundle of filaments is to take an extrudable material (such as a glass, ceramic, polymer or plastic in a softened or semi-molten state) and force it through a rigid die containing small holes with cross sections of the desired shapes, and slice the material after it passes through the die; additional hardening stages may take place during this process, at points prior to or after slicing; also, after passing from the die the filaments may undergo further pulling and stretching to reduce their cross sectional dimensions, while maintaining their cross sectional shapes, prior to slicing. Another method for making such filaments is by casting from a mold. Such a process is similar to the casting method outlined in the above claim. The mold consists of two flat plates, one of which has many closely spaced, fine, straight grooves in it, that define filaments with the desired cross sections. The casting material is placed between the plates in a liquid or semi-solid state, and the plates are forced together to force the material into the grooves. Or, the grooves can be continued to the edges of plate, the plates placed together, and the casting material forcibly injected through the groove openings on one side. The casting material is then allowed to harden, and the filaments are removed from the mold as sheet or a bundle, which is then sliced to release pools of particles. For yet another method of making suitable filament bundles, a macroscopic glass or plastic rod is made having the desired cross-sectional shape. The rod is then softened (by heat or chemical treatment), and stretched and pulled to reduce its cross-sectional area, which retains its shape. As the material is repeatedly pulled and doubled over on itself, it ultimately forms a bundle of microscopic filaments, which can then be sliced to release particles. Starting from a single such rod of material will produce particles all of one shape, or several such rods of different shape may be bundled together before the pulling and folding, in order to make multiple shapes at once. A final method of making a suitable filament bundle it to produce isolated filaments with shaped cross sections by any of the above methods of extrusion, casting or pulling, and these finished filaments are then formed into a bundle with a cross section of N filaments, either by grouping individual filaments, or by repeated folding, doubling, winding or braiding of a one or more filaments. The bundle so formed is then sliced, each slice releasing N particles, which may then undergo any final hardening procedures.

### Example 27

### A General System for Multiplex Handling of Probes Using Shape Encoded Particle Carriers

Probes are attached to shapes in individual bulk reactions; each such reaction undergoes individual quality control assessment; accepted shape-probe conjugate batches for distinct shape-probe conjugates are pooled into a master mix, which is dispensed in aliquots of sufficient size that we on average expect multiple representatives of each distinct probe (oversampling); such an aliquot is added to sample for an assay reaction; subsequent to the reaction, the particle pool is recovered, washed, undergo any additional post-treatments for fixing, activation, or signal enhancement; the resulting particle shapes and reporter signals are acquired with a suitable imaging system, preferably by dispensing the particles onto a reading surface and imaging them in parallel for shape and reporter signals; the acquired data undergoes computer processing of the images to identify the particles and associate the reporter signals, and produce a final datafile of probes, corresponding reporter signals, and any associated uncertainty measures. The imaging system used to read shape could be closely related to that used to obtain the reporter signal (e.g. both could be the same fluorescent image, or white light and fluorescent images taken simultaneously through different filters), or quite distinct (reporter signal used to sort particles into different reporting groups, with subsequent imaging of shapes to identify particles in each group), but typically might consist of registering multiple spatial images, one which records the shape data, and the others which record the reported signals in distinct channels

### Example 28

### Creating a Heavily Oxidized Silicon Surface on Shape Encoded Particles to Facilitate Standard Probe Attachment Procedures

Many standard methods of attachment are for glass (SiO2) surfaces, thus methods for getting the shape encoded particle surface into a similar state enables the use of many standard attachment techniques. Oxidation methods include hydrogen peroxide or thermal treatment in an oxygen-rich atmosphere.

### Example 29

### A Method of Multiplexing Probes That Must be Maintained Under Liquid/Buffering Conditions

With shape encoded particles, the process of probe attachment and storage can be done entirely under suitable liquid/buffering conditions needed to maintain delicate probes, such as proteins in their natural conformation or living cells. The final multiplexing can also be limited to compatible sets of probes, to further maintain viable conditions.

### Example 30

### A Method for Producing a Multiplex Set of Encoded Protein Probes that Retain the Natural Conformation

Many proteins need to be maintained in a buffer to retain their native form, and the shape-encoded particles can always be maintained under such conditions, during and after attachment.

### Example 31

### Shape Encoded Particles Coated with Polymer Matrix Material for Universal Probe Attachment

Various polymer matrix materials, such as nitrocellulose or polyacrylamide, can be use to bind many types of nucleic acid or other probes, and also can hold probes by trapping them in place, with or without subsequent cross linking reactions. These polymer matrices can be attached to shape encoded particles to provide a universal probe attachment system. In contrast to specific probe attachment protocols, it the present inventors likewise are putting a polymer matrix onto the particles, which could then “trap” and hold many types of biological probe in place, DNA, protein, cell organelle.

### Example 32

### Probe Attachment Protocols For: DNA or Other Nucleic Acids

The methods are generally adaptations of methods for attaching DNA to glass (SiO₂) surfaces; First, heavily oxidize the Silicon surface to create a glass equivalent, and then use standard methods that attach chemical intermediates to the (SiO₂), such as silane or thiol, to which DNA probes can be coupled.

### Example 33

### Probe Attachment Protocols for: Proteins or Antibodies

The methods are generally adaptations of methods for attaching proteins to glass surfaces; heavily oxidize the Silicon surface to create a glass equivalent, and then attach chemical intermediaries to the SiO₂, such as Nickel, to which the proteins can be bound by standard means.

### Example 34

### Probe Attachment Protocols for Cells or Cell Membranes

An important and novel enhancement to this process of growing cells on shapes, which the inventors have already validated experimentally is to lay out the shapes on a ‘low growth’ support surface prior to cultering cells, so that the cells will preferentially adhere and grow on the shape surfaces, and not on the adjacent support surface. This prevents cells from migrating off the shapes, or adhering to both the shape and support surface, which results in cell loss or damage when the shapes are moved off of the support, and also interferes with accurate imaging of the shape edges for shape identification. The ‘low growth’ support is typically a plastic or glass plate that is simply not coated with the standard functional groups needed for normal cell attachment and growth in cell culturing. The methods are generally adaptations of methods for growing cells to attached to glass surfaces; heavily oxidize the Silicon surface to create a glass equivalent, and attach suitable peptides to which cell membranes bind, as in standard procedures.

### Example 35

### Methods of Assembling Shape Encoded Particles for Imaging

To facilitate reading of shapes by the imaging system, a variety of methods can be used to assemble a pool of shape encoded particles so that they are in their standard “flat” orientations, stationary, non-overlapping, efficiently packed and layed in a format convenient for the imaging. Specific techniques could include combinations of the following: “random assembly”, in which the particles settle randomly onto a flat, inert surface (e.g. a glass microscope slide); the use of mechanical vibration to help flatten the particles into a monolayer and pack them place on the assembly surface; the use of centrifugation to drop the particles out of solution faster or increase their friction against the assembly surface; change of liquid medium, where the particles are filtered out from one solution and re-suspended into another better suited to the assembly process; floating particles on a denser liquid layer starting with the particles highly dispersed to obtain a monolayer, and then slowly restricting their available fluid area so as to efficiently pack them, either by draining away the liquid from below through a narrowing funnel, using a mechanical means to “corral” the free floating particles into a reduced area; creating a flow that carriers the particles through a narrowing channel that dispenses them out in a controlled monolayer on a flat surface; using a flat surface that is specifically sticky to the particles (via chemical adhesives, or magnetic or electrical forces), combined with mechanical agitation, in such a way that the particles are in random motion until they land flat on the sticky surface, at which point they are fixed in place; dispensing particles onto a patterned surface that encourages organized positioning, by trapping the particles in dimples or depressions. Particles could also be specially shaped, along with the reading surface, so as to fall and interlock with the surface in a more restricted manner. The present inventors have discovered the advantages of doing this by spreading the particles out and fixing them in place for 2-D imaging, since this is a fully parallel handling procedure, and the motivation is to increase throughput via parallelism wherever possible, which this does.

### Example 36

### Algorithms for Reading Shapes

To process shape image data requires specific algorithms for enhancing the image quality (including removing noise, blur, or clutter), for segmenting out the individual particles, for decoding their shapes, associating any reporter signals, quantifying the reporter signals, assigning uncertainty measures to the shape decoding and reporter signal quantification, and combining these algorithms with a software interface that allows specification of input data files, setting of algorithm parameters, displaying progress and results of the decoding, and saving the results in a suitable database format. In our preferred implementation, the processing algorithm is as follows: the algorithm takes as input the general parameters of: the anticipated base shape (square, circle, etc), its size specification (edge, diameter, etc) measured in pixels, type of notching (positional, frequency, etc) and possible number of notches, and a database of allowed shape codes and their associated carrier probes IDs, if any, and the number of reporter signal channels images that accompany the monochrome shape decoding image, and an intensity threshold for the shape image that is used to separate foreground from background in the image; given these general parameters, further input consists of the shape decoding image, and the associated reporter decoding images—there may be data for multiple impendent shape decoding image with associated reported images, in which case these are processed as follows independently, either serially, or using parallel processing hardware, or distributed across a cluster of computers for greater speed; the shape image first undergoes denoising and deblurring (this is done using a simple median filter for high resolution images, but requires general deconvolution methods, such as Total Variation Diminishing image restoration, for low resolution images); next, it undergoes a threshold-based segmentation, identifying isolated, connected regions of pixels that exceed the intensity threshold, and segmented regions that are too small (likely debris) or two large (likely overlapping particles) to be single shapes are eliminated from further consideration; each segmented region is then processed independently, and the instances can be analyzed serially, or using parallel processing hardware, or distributed across a cluster of computers for greater speed; first, each segmented region has a boundary curve traced as a series of points, by interpolating to the precise location of the threshold intensity; next, the boundary curve has the base shape fit to it, by first estimating its center and orientation, and then searching through refinements in these to obtain a best fit to a desired tolerance; then, the points of intersection between the base shape boundary (displaced slightly outward or inward) and the actual shape boundary are determined, and these intersection points define the notching pattern and thus identify the shape; the discrepancy between this list of intersection points and the theoretically predicted list of points for the ideal shape and its corresponding ideal base shape are used as the uncertainty of the decoding. Next, each successive reporter channel image is aligned with the shape decoding image, and for each particle previously decoded, its corresponding base shape is used to isolate a set of pixels in the reporter image that would correspond to the unobstructed central region of the particle, and the reporter pixel values are converted into a robust average and deviation value, used as the reporter signal and uncertainty in that signal, and are associated with that decoded particle. The results are saved in a table that stores the shape code, the associated probe ID, and the successive reporter channel values, along with the uncertainties in the shape decoding and reporter signals.

### Example 37

### The Shapereader Type of Software Takes in Images of SEP's, and Any Associated Reported Channel (E.G. Fluorescent) Images, and Decodes the Shapes, Measures the Reporter Signals, and Associated Signals Back to the Probes Encoded by the Shapes

The software which implements these algorithms of the previous claim provided a user interface consisting of pull-down menus, check-boxes, numerical input forms and file selectors for specifying the inputs described above; it then displays each original shape decoding image in a separate window, and also displays the cleaned up and segmented form of the image, with segments indicated visually by distinct colors; then in real time it produces a spreadsheet-style layout, line by line, where each row is data for a different particle, consisting of all the relevant images and alphanumeric data; specifically, each row contains a series of fields which show a portion of the original image including the particle, the resulting ideal shape fit to this image segment, the shape decoded ID, the decoding uncertainty, the associated probe ID, and the reporter signals and their uncertainties, and false color image segments from the various reporter images, as well as a composite false color image of all reporter signals and the shape image; data from multiple shape decoding images specified at the input are assembled into a single such sheet; the resulting image/data spreadsheet can be sorted by any of the quantitative measures (signals or uncertainties), or by the shape codes, and it also provides an inspector selection mode which can be used to examine the image data of a given row in magnified detail, and to make manual edits to the shape determination or signal determination in this mode, which are subsequently updated into the sheet. The software stores this output sheet in a database, which can be subsequently recalled in this graphical format, and can also export a table containing just the shape code, probe ID and quantitative data.

### Example 38

### A Parallel Stem Cell Differentiation Screening Assay

The present inventors have discovered a special case of the general treatment tracking assay, by the application to finding new ways to direct differentiation of stem cells into useful types. Stem cells are typically led to differentiate into a desired cell type by exposing them to a series of growth factors, or by systematically withdrawing such factors. It may be desirable to screen many such treatment series, in order to find a treatment producing a desired cell type, or to classify treatments by which type they produce. We use a special case of the treatment tracking assay from the above testing regimen to screen a large number of treatment series in parallel. Here, let the treatments in each Ti correspond to exposure to or withdrawal of different growth factors. The initial material is the stem cells, cultured onto the N shape encoded particles. The final outcome is measured by a reporter for a particular cell type (for example, staining for known marker proteins, or looking for special cell morphology, or a functional challenge), or a classification of the cells by their differentiated type.

### REFERENCES

[1] [2] Fodor, S. P., Read, J. L., Pirrung, M. C., Stryer, L., Lu, A T. and Solas, D (1991) Light-directed spatially addressable parallel chemical synthesis. Science, 251, 767-773.
[3] Lockhart, D. J., Dong, H., Byrne, M C., Follette, M. T., Gallo, M. V., Chee, M. S., Mittamann, M., Wang, C., Kobayashi, M., Horton, H. and Brown, E. L. (1996). Expression monitoring by hybridization to high density oligonucleotide arrays. Nat. Biotechnol., 14, 1675-1680.
[4] Hughes T R, et al Expression profiling using microarrays fabricated by an ink-jet oligonucleotide synthesizer. Nat Biotechnol. 2001 April; 19(4):342-7.
[5] Pinkel D, Segraves R, Sudar D, Clark 5, Poole 1, Kowbel D, Collins C, Kuo W L, Chen C, Zhai Y. Dairkee S H, Ljung B M, Gray J W, Albertson D G. High resolution analysis of DNA copy number variation using comparative genomic hybridization to microarrays. Nat Genet. 1998. October; 20(2):207-11.
[6] Singh-Gasson S, Green R D, Yue Y, Nelson C. Blattner F, Sussman M R, Cerrina F. Maskless fabrication of light-directed oligonucleotide microarrays using a digital micromirror array. Nat Biotechnol. 1999 October; 17(10):974-8.
[7] Dill K, Stanker L H, Young C R. Detection of salmonella in poultry using a silicon chip-based biosensor. I Biochem Biophys Methods 1999 Aug. 30; 41(I):61-7
[8] Sosnowski R G, Tu E, Butler W F, O'Connell J P, Heller Mi. Rapid determination of single base mismatch mutations in DNA hybrids by direct electric field control. Proc Natl Acad Sci USA. 1997 February I 8;94(4):I I J9-23.
[9] Fulton, R. L., McDade, R. L., Smith. P. L., Klenker, Li. and Kenman. J. R., Jr (1997) Advanced multiplexed analysis with the FlowMetrix System. Clin. Chem., 43, 1749-1756.
[10] Han., M., Gao, X., Su, J. Z. and Nie, S. (2001) Quantum-dot-tagged microbeads for multiplexed optical coding of biomolecules. Nat. Biotechnol., 19, 63 1-635.
[b 11] Fercuson. J. A., Boles. T. C., Adams. C F. and Walt. D R. (1996) A fiber-optic DNA biosensor microarray for the analysis of gene expression. Nat. BiotechnoL. 14. I681-I684.
[12] Moran. E J. El al. (1995) Radio-frequency tag encoded combinatorial library method for the discovers' of tripeptide-substituted cinnamic acid inhibitors of the protein tyrosine phosphatase PTP1 B. i. Am. Chem. Soc., 117. 10787-10788.
[13] Nicewarner-Pena.5. R. Freeman. R. G. Reiss. B. D. He. L. Pena. Di. Walton. I D. Cromer. R. Keating. C. D. and Natan. M. J. (200I) Submicrometer metallic barcodes. Science. 294. 137-41.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. A process for generating novel enhanced shape encoding particles (SEP's) which maximizes particle encoding capacity and reserves a centralized probe attachment zone, comprising the steps of:
fabricating a planar poly-layered silicone wafer flake further comprised of a first micron-scale thickness polycrystalline Si layer disposed upon a bottom thinner dissolvable layer of SiO₂;
photolithographically etching with reactive ions desired geometric shape outlines in the top Si layer;
releasing resulting shaped flakes by dissolving the bottom dissolvable layer of SiO₂ with HF acid whereby said desired geometric shape outlines further comprise peripheral notches extending not more than ⅙th of the diameter of the resulting shaped flakes into a central region of the resulting shaped flakes.

39. (canceled)

40. A product produced by the process of claim 38.

41. In a process for encoding the identity of microscopic particles by shape, wherein such particles can be combined in large numbers while remaining readily distinguishable and having their individual identities recovered, the improvement comprising:
fabricating a multiplicity of shape encoded particles (SEP's) each having a top surface and a bottom surface and each having a unique geometric configuration wherein each of said multiplicity of SEP's is effective for being readily arranged such that each of the top and bottom surfaces rests in a plane parallel to a plane of a surface upon which the bottom surface is disposed enabling display of a definitive outline when imaged by a suitable technique.

42. A novel enhanced SEP product, produced by the process of claim 41, wherein a definitive outline enables identification of the SEP and any material previously associated with the SEP through at least one of binding and contact with the SEP.

43. A novel enhanced SEP product, produced by the process of claim 41, having a dimensional range extending from the nanometer to the millimeter scale.

44. A novel enhanced SEP product, produced by the process of claim 41, wherein shape detection is accomplished by at least one imaging technique selected from the group consisting of optical microscopic imaging, near field microscopy, electron microscopy, scanning-tunneling microscopy and atomic force microscopy.

45. A novel enhanced SEP product, produced by the process of claim 41, wherein resolution of the definitive outline of said SEP is facilitated by automated image recognition software.

46. A novel enhanced SEP product, produced by the process of claim 41, wherein the SEP has a diameter of less at least about three microns and said unique geometric configuration is less than the wavelength of visible light.

47. A novel enhanced SEP product, produced by the process of claim 41, effective to transport organic matter bound to the top surface of said SEP.

48. A novel enhanced SEP product, produced by the process of claim 41, effective to transport inorganic matter attached to the top surface of said SEP.

49. A novel enhanced SEP product, produced by the process of claim 41, wherein said SEP is effective for use in conjunction with numerous other novel enhanced SEP's for massive simultaneous tracking of material bound to the top surface of said SEP's as the SEP's are pooled and put through at least one of a simple reaction and a series of pooled reactions.

50. A method for generating shape encoded response classes for use in subsequent assays, comprising the steps of:
providing a multiplicity of novel enhanced SEP's;
attaching probes to each of the multiplicity of SEP's;
reacting the multiplicity of SEP's having bound probes against a sample;
physically sorting the resulting products into at least two classes using respective strengths of reporter signals; and,
decoding the results by automated shape imaging by class.

51. The method of claim 50, wherein the providing step further comprises:
fabricating bulk quantities of SEP's.

52. The method of claim 11, wherein the attaching step further comprises undergoing an attachment reaction to form SEP-probe conjugates.

53. The method of claim 52, wherein the reacting step further comprises pooling the SEP-probe conjugates and dispensing randomly sampled aliquots.

54. The method of claim 53, wherein the sorting step further comprises performing individual assays.

55. The method of claim 54, wherein the decoding step further comprises using an automated imaging system.

56. The method according to claim 55, wherein the decoding step further comprises using shape recognition software to generate a desired form and format for a resulting data set.

57. The method of claim 56, wherein massively multiplexing assays are accomplished using fewer spatial limitations and mixing constraints relative to existing methods of multiplexing probes.

58. The process of claim 41, wherein the fabricating step further comprises maintaining a special free region optimal for probe attachment and detection on the top surface of said SEP, further reducing a likelihood of artifactual debris masking the unique geograph features imaged.

59. A product, produced by the process of claim 58, which includes an addressable microreactor comprised of an encoded microwell.

60. The process of claim 41, further comprising one-bit SEP imaging.

61. In a generally planar shape encoded particle (SEP) made from a geometric base shape for arbitrarily large capacity and unambiguous multiplexed decoding, the improvement which comprises:
an adjustable coding capacity defined by a number of independent notches extending along a peripheral edge surface of the SEP whereby N notches encode for 2^{N} shapes.

62. The SEP of claim 61, wherein the systematic notch patterns are defined by a following algorithm (“notching equation”):
S[C](t)=b₀(t)+c₁b₁(t)+c₂b₂(t)+ . . . +c_{N}b_{N}(t) i.
ii. given a code word consisting of N digits in base k,
C=(c₁, c₂, . . . , c_{N}),
iii. where cᵢε{0, 1, . . . , k−1} (e.g., k=2 is binary code, each cᵢ is 0 or 1), it is associated with a 2-dimensional closed curve S[C]—the “shape”—defined by the “notching equation”
iv. where tε[0,1] is a parameterization of the base shape boundary curve.
Here, b₀(t) represents the equation of the base shape boundary, and the other bᵢ(t) represent the equations of the basis of curves corresponding to the distinct potential “notches”. The number of distinct code words, C, is k^{N} (2^{N} for binary coding).

63. The SEP of claim 62, further comprising being distinguishable in any orientation by having at least an indicum to differentiate the spatial orientation of the SEP in terms of the relative position of the SEP upon at least one of a substrate upon which it is disposed and a material in which it is embedded.

64. The SEP of claim 63, wherein the image of S[C] is the boundary of a connected open set, further defined as the SEP is capable of being repeat manufacturable in that if the shape was cut from a material sheet, the SEP is substantially free of dangling or disjoint parts interfering with the ability to distinguish the shape of the SEP.

65. The SEP of claim 64, wherein a perturbing basis bᵢ(t) corresponds to isolated notches positioned about the peripheral edge of the geometric base shape.

66. The SEP of claim 65, wherein said base shape is a square; and the isolated notches further comprise completely disjoint smaller square notches.

67. The SEP of claim 64, wherein a perturbing basis bi(t) corresponds to distinct frequencies of sinusoidal ripples defined by distinct Fourier Modes along the boundary of a circular base geometric shape.

68. The SEP of claim 64, wherein a perturbing basis bi(t) corresponds to the first N nodes of a wavelet basis, defined by positional frequencies having specific mathematical properties for curves along the geometric base shape perimeter.

69. The SEP of claim 61, further comprising a multiresolution (fractal) curve defined by a following algorithm:
S[Cᵢ₊₁](t)=S[Cᵢ](t)+cⁱ₁bⁱ₁(t)+cⁱ₂bⁱ₂+ . . . +cⁱ_{N}bⁱ_{Ni}(t) i.
ii. given any series of M base k code words of the type above, X={C₁, . . . , Cᵢ, . . . , C_{M}}, the single shape defined by this entire series, S[X], is defined iteratively as follows: the first iteration, S[C₁], is defined as usual above, relative to some base shape;
iii. where S[Cᵢ] plays the role of the base shape for this step, and bⁱₘ is a basis of perturbations along this new base shape. These will typically be a reduced scale form of the type of notches used on the coarsest scale. The final or limiting shape produced by this process, S[C_{M}], is the shape S[X]. The number of encoding shapes described this way is the number of encoding vectors, X, which is k^{N}, where N is now the total number of encoding digits in X, N=N₁+N₂+ . . . +N_{M}.

70. The SEP of claim 69, further comprising being distinguishable in any orientation by having at least an indicum to differentiate the spatial orientation of the SEP in terms of the relative position of the SEP upon at least one of a substrate upon which it is disposed and a material in which it is embedded.

71. The SEP of claim 70, wherein the image of S[C] is the boundary of a connected open set, further defined as the SEP is capable of being repeat manufacturable in that if the shape was cut from a material sheet, the SEP is substantially free of dangling or disjoint parts interfering with the ability to distinguish the shape of the SEP.

72. The SEP of claim 64, further defined by a concise scalable and general specification language comprising a definitive size for the geometric base shape and a plurality of basis coefficients further describing the shape.

73. A process for designing a photolithography mask for high density fabrication of SEP's, comprising the steps of:
choosing a standard polygon which polygon surrounds a desired shape circumferentially;
replicating the standard polygon in a high density closed space regular array for defining available shape positions by covering the available mask area with N polygons; and
populating available locations on the mask given a set of N desired shapes.

74. The process of claim 73, implemented in software further comprising the steps of:
inputting a mask size, a standard polygon size and a specification history listing of desired N shapes;
translating the description into mask pattern specifications; and
automatically producing as output a mask specification file suitable for reading a pattern generator system used to fabricate the mask.

75. The process of claim 74, further comprising the steps of:
placing the N desired shapes on a mask for a single wafer;
etching the single wafer;
releasing the entire set of shapes; and
collecting the entire set of shapes into a single pool.

76. The process of claim 73, further comprising the steps of:
using the resulting mask to perform reactive-ion-etching of a silicon-on-insulator wafer; by,
reactive ion etching for sufficient time to cut through to the substrate;
subdividing the etched wafer into sub-sections for subsequent handling;
physically releasing the etched poly-crystalline silicon by dissolving the substrate with a hydrofluoric acid treatment;
creating a resulting pool of freed SEP's;
surface treating the freed particles with at least one of heating and hydrogen peroxide treatment to prepare the SEP's for subsequent handling; and,
storing the finished SEP's in purified H₂O.

77. The SEP of claim 66, consisting essentially of a flake derived from a wafer of silicon.

78. (canceled)

79. The SEP of claim 66, further comprising a magnetic material selected from the group consisting of magnetic, ferromagnetic and magnetizable components.

80. A method of using shape encoded particles (SEP's) for DNA analysis, which comprises the steps of:
providing a multiplicity of SEP's having distinct and imageable shapes;
binding each of said multiplicity of SEP's having distinct shapes to a desired number of biological probes;
hybridizing the resulting combinations in solution; and
acquiring data in the form of reporter signals from the bound material.

81. The method of claim 80, said providing step further comprising each of the multiplicity of SEP's having the inherent ability to both identify material bound to them and to track history of exposure as processing reaction steps alter their respective states or the state of organic probes bound to them.

82. The process of claim 38, said centralized probe attachment zone further comprising at least an encoded microwell having a diameter 1 ranging from at least about 1 micron to 100 microns and a volume less than or equal to 1 nano liter.

83. A product, produced by the process of claim 82.

84. A genomic analysis method, using the product of claim 82, comprising the steps of:
coupling biological probes to the novel enhanced SEP's having microwells;
mixing all of the novel enhanced SEP's having microwells together;
loading reaction mixtures into the microwells by soaking;
sealing the reaction wells;
and monitoring the reaction.

85. The method of claim 84, further comprising:
transferring the loaded particles from their aqueous loading solution into oil,
forming a tension seal of the microwells;
transferring the aqueous loading solution and particles onto a soft polymer support surface, and impressing them into the surface with sufficient force based up the centrifuge acceleration to form a pressure seal of those microwells facing downward into the polymer;
transferring the aqueous loading solution and particles onto a support surface and impressing upon them a compliant polymer sheet with adequate force to form a pressure seal on those microwells facing upward into the sheet; and
undergoing a capping reaction whereby a multiplicity of spherical particles are introduced into the aqueous loading solution having a predetermined size and surface coating for fitting the multiplicity into the microwell openings and seal the microwell openings.

86. The method of claim of claim 85, further comprising Polymerase Chain Reaction (PCR) detection of DNA and RNA.

87. The method of claim 86, the PCR being used for DNA analysis whereby the shape encoded microwells are preloaded with PCR detection primers bound to the microwell walls having different shapes carrying different detection primers, and the pool of the microwell particles is introduced into the DNA sample to be analyzed, loaded by soaking and then sealed, reacted with PCR and imaged for a reporter signal to detect and quantify whether the subject DNA sample contains fragments corresponding to the involved detection primers.

88. The method of claim 87, further comprising using the reporter signal to for biodefense monitoring by simultaneously screening a sample for DNA from a multiplicity of pathogenic microorganisms and different strains of particularized pathogens.

89. The method of claim 85, further comprising Enzyme Linked Immunosorbant Assay (ELISA) detection of proteins.

90. The method of claim 89, whereby the shape encoded microwells are preloaded with ELISA detection antibodies bound to the microwell walls having different shapes containing different detection antibodies for different proteins, and the pool of the microwells is introduced into the protein sample to be analyzed in solution, loaded by soaking, and sealed, reacted and imaged for a reporter signal to detect and quantify whether the sample contains proteins corresponding to subject detection antibodies.

91. The method of claim 90, further comprising using the reporter signal to for biodefense monitoring by simultaneously screening a sample for DNA from a multiplicity of pathogenic microorganisms and different strains of particularized pathogens.

92. The genomic analysis method of claim 85, the monitoring step further comprising using a fluorescent microscope or scanner to detect at least one of a positive signal (reaction) and a negative signal (no reaction).

93. A method of use of the SEP of claim 61, as an embedded identification device for bulk materials, whereby a multiplicity of said SEP's are at least one of surface coated onto workpieces; embedded into solid materials during manufacturing; mixed into powdered materials; and suspended in liquid or gas phase materials.

94. A method of use of the SEP of claim 62, as an embedded identification device for bulk materials, whereby a multiplicity of said SEP's are at least one of surface coated onto workpieces; embedded into solid materials during manufacturing; mixed into powdered materials; and suspended in liquid or gas phase materials.

95. A method of use of the SEP of claim 61, as an embedded identification device for military, police, criminal or terrorist activities by rendering specialty plastic, ceramic and metallic items traceable to their owners, manufacturers, or distributors.

96. The method of claim 95, further comprising emplacing SEP's within explosive devices.

97. A method of use of the SEP of claim 61, as an embedded identification device for high value components subject to theft.

98. A method of use of the SEP of claim 61, as an embedded identification device for sample tracking in forensic or biomedical analyses.

99. A method of use of the SEP of claim 61, as an embedded identification device for quality control in mixture based procedures.

100. A method of use of the SEP of claim 61, as an embedded identification device for materials released into the environment.

101. A method of use of the SEP of claim 61, as an embedded identification device for rapid screening of different trial mixtures having a desirable property or ingredient.

102. A method of use of novel enhanced SEP's comprising the steps of:
generating a library of possible combinations of an identifiable set of molecular building blocks;
testing the molecular building blocks for a set of desired properties;
storing results on a number of N SEP's.

103. The method of claim 102, further comprising providing a stem cell line, cultured onto the N shape encoded particles a tracking assay from the to screen a large number of treatment series corresponding to exposure to or withdrawal of different growth factors and measuring by a reporter for a particular cell type.

104. A shape encoded particle (SEP) based combinatorial synthesis process, comprising the steps of:
providing a multiplicity of novel enhanced SEP's which are effective for two-dimensional image creation over a massive number of possible combinations of geometric shapes by enabling display of a definitive outline when imaged by a suitable technique;
synthesizing directly onto the SEP's a predetermined range of combinations of chemical moieties and entities to be systematically tested for functionality;
whereby an encoded screening assay is created of the directly synthesized combinations of chemical moieties and entities such that a library of the same is created.

105. The process of claim 104, wherein an SEP combinatorial treatment tracking assay is generated by a series of steps, comprising, in combination:
starting with a series of cells;
tracking the response of the cells to a predetermined series of possible sequential treatments by a set of factors, wherein the order of application is important;
archiving the resulting data by SEP information; and
repeating the process X times as needed.

106. The process of claim 105, the tracking step further comprising:
carrying out a predetermined universe of possible combinations of treatment on a material;
recording the outcome of the possible treatment series;
dividing a particle pool of resulting outcomes onto N distinct SEP shapes;
pooling the resulting SEP's;
arbitrarily dividing the SEP's into a plurality of treatment sub-groupings;
imaging the sub-groupings in such a way that the outcome is associated with the shape of each particle.

107. The process of claim 106, the carrying out step further comprising:
providing a set of chemical building blocks;
linking the building blocks to form a k-mer, or string of K linked blocks;
preparing a pool of N distinct SEP shapes;
undertaking a derivatizing reaction on the pool to prepare the SEP particles surfaces;
dividing the SEP pool randomly into M equal sub-pools;
imaging each sub-pool to record which shapes are included; and
repeating the process for K times.

108. A product produced by the process of claim 107, which is a shape encoded library.

109. The process of claim 105, the SEP combinatorial treatment tracking assay is effective for producing a library of serially treated materials or an assay for a treatment series producing a design effect on the starting material.

110. A method of use of novel enhanced shape encoded particles (SEP's) for structural geometric forensic reconstruction comprising the steps of:
creating a pool of N distinct SEP's, from a single etching process;
applying the SEP's to the surface of a completed structure;
imaging the entire structure in a series of shape recording images mapped in three ordinal planes onto the structure; and,
retracing the structure from a fragment following a partially destructive event.

111. A method of use novel enhanced SEP's for seeding cultured pearls, comprising the steps of:
emplacing an SEP as a seed particles with a pearl culturing medium in the place of a standard seeding particle such as an oyster shell spherule;
recording the encoded identity of the SEP; and,
imaging the SEP non-destructively with x rays;
for at least one of authentication, tracing, theft prevention and reclamation.
